(19) United States
(12) Patent Application Publication
(10) Pub. No.: US 2026/0255845 A1
(43) Pub. Date: Aug. 27, 2026

(54) DISPLAY DEVICE, ELECTRONIC DEVICE INCLUDING THE SAME, AND METHOD OF MANUFACTURING THE DISPLAY DEVICE

(71) Applicant: Samsung Display Co., LTD., Yongin-si (KR)

(72) Inventors: SEHO LEE, Yongin-si (KR); JAEHOON HWANG, Yongin-si (KR)

(21) Appl. No.: 19/448,776

(22) Filed: Jan. 14, 2026

(30) Foreign Application Priority Data
Jan. 17, 2025 (KR) 10-2025-0007415

(51) Int. Cl. H10K 59/80; H10K 59/12; H10K 59/121; H10K 59/124; H10K 102/00

(52) U.S. Cl. CPC H10K 59/80522; H10K 59/1201; H10K 59/1213; H10K 59/124; H10K 2102/351

(57) ABSTRACT

A display device includes a substrate, a circuit layer arranged on the substrate, a first electrode arranged on the circuit layer, at least one auxiliary electrode arranged on the circuit layer and electrically separated from the first electrode, an organic layer arranged on the first electrode and the at least one auxiliary electrode, the organic layer defining an opening therein exposing a portion of the at least one auxiliary electrode, and a second electrode arranged on the organic layer to overlap the first electrode and the at least one auxiliary electrode, where the second electrode is electrically connected to the at least one auxiliary electrode through the opening of the organic layer, and the at least one auxiliary electrode includes a first auxiliary electrode having a variable thickness.

This application claims priority to Korean Patent Application No. 10-2025-0007415, filed on Jan. 17, 2025, and all the benefits accruing therefrom under 35 U.S.C. § 119, the content of which in its entirety is herein incorporated by reference.

### BACKGROUND

### 1. Field

One or more embodiments relate to a display device, an electronic device including the same, and a method of manufacturing the display device.

### 2. Description of the Related Art

A display device is a device that receives information related to an image and displays the image. A display device may be utilized as a display unit of a small-sized product, such as a portable phone, and may also be utilized as a display unit of a large-sized product, such as a television.

A display device includes a plurality of pixels that receive electrical signals and emit light to display an image externally. Each pixel includes a light-emitting element, for example, an organic light-emitting diode OLED as the light-emitting element for an organic light-emitting display device. Typically, an organic light-emitting display device includes thin-film transistors and OLEDs on a substrate, and the OLEDs emit light by themselves to operate the organic light-emitting display device.

An electronic device may provide users with visual interfaces required by the users through a display device.

### SUMMARY

One or more embodiments provide a display device having uniform brightness and improved reliability and a method of manufacturing the same. However, these objectives are exemplary and the scope of the disclosure is not limited thereby.

According to one or more embodiments, a display device includes a substrate, a circuit layer arranged on the substrate, a first electrode arranged on the circuit layer, at least one auxiliary electrode arranged on the circuit layer and electrically separated from the first electrode, an organic layer arranged on the first electrode and the at least one auxiliary electrode, the organic layer defining an opening therein exposing a portion of the at least one auxiliary electrode, and a second electrode arranged on the organic layer to overlap the first electrode and the at least one auxiliary electrode, where the second electrode is electrically connected to the at least one auxiliary electrode through the opening of the organic layer, and the at least one auxiliary electrode includes a first auxiliary electrode having a variable thickness.

In an embodiment, the first auxiliary electrode may include a first area having a constant first thickness, and a second area connected to the first area and having a thickness which varies between a second thickness as a maximum thickness and a third thickness as a minimum thickness.

In an embodiment, the second area may be formed in an area of the first auxiliary electrode which overlaps the opening in a plan view.

In an embodiment, the first area may be adjacent to an edge of the opening, and the second area may overlap a center of the opening in the plan view.

In an embodiment, the thickness of the second area may range from 5% to 300% of the constant first thickness.

In an embodiment, the at least one auxiliary electrode may further include a second auxiliary electrode having a constant thickness.

In an embodiment, the circuit layer may include a transistor layer and an insulating layer arranged on the transistor layer, and the first auxiliary electrode may be arranged on the insulating layer.

In an embodiment, the organic layer may include an emission layer, and the second electrode may be directly connected to the at least one auxiliary electrode through the opening such that the emission layer is not disposed between the second electrode and the at least one auxiliary electrode.

In an embodiment, the first auxiliary electrode may be arranged at a same layer as the first electrode.

According to one or more embodiments, a method of manufacturing a display device includes preparing a substrate, forming a circuit layer on the substrate, forming a first electrode and at least one auxiliary electrode electrically separated from the first electrode on the circuit layer, forming an organic layer including an emission layer on the first electrode and the at least one auxiliary electrode, forming an opening penetrating the organic layer and forming an auxiliary electrode of the at least one auxiliary electrode into a first auxiliary electrode having a variable thickness, and forming a second electrode on the organic layer to overlap the first electrode and the at least one auxiliary electrode, where the second electrode is electrically connected to the at least one auxiliary electrode through the opening of the organic layer.

In an embodiment, the forming the opening and forming the auxiliary electrode into the first auxiliary electrode may include a process of irradiating a laser beam onto the organic layer.

In an embodiment, the first auxiliary electrode may include a first area having a constant first thickness, and a second area connected to the first area and having a thickness which varies between a second thickness as a maximum thickness and a third thickness as a minimum thickness.

In an embodiment, the thickness of the second area may range from 5% to 300% of the constant first thickness.

According to one or more embodiments, an electronic device includes an input module configured to receive a command or data to be used in the electronic device from outside, a processor configured to process input data received from the input module and output image data or command data, a memory storing input data or output data used by the processor, and a display device configured to implement at least one image by the processor, where the display device includes a first electrode arranged on a circuit layer, at least one auxiliary electrode arranged on the circuit layer and electrically separated from the first electrode, an organic layer arranged on the first electrode and the at least one auxiliary electrode, the organic layer defining an opening therein exposing a portion of the at least one auxiliary electrode, and a second electrode arranged on the organic layer to overlap the first electrode and the at least one auxiliary electrode, and the second electrode is electrically connected to the at least one auxiliary electrode through the opening of the organic layer, and the at least one auxiliary electrode includes a first auxiliary electrode having a variable thickness.

In an embodiment, the first auxiliary electrode may include a first area having a constant first thickness, and a second area connected to the first area and having a thickness which varies between a second thickness as a maximum thickness and a third thickness as a minimum thickness.

In an embodiment, the second area may be formed in an area of the first auxiliary electrode which overlaps the opening in a plan view.

In an embodiment, the first area may be adjacent to an edge of the opening, and the second area may overlap a center of the opening in the plan view.

In an embodiment, the thickness of the second area may range from 5% to 300% of the constant first thickness.

In an embodiment, the at least one auxiliary electrode may further include a second auxiliary electrode having a constant thickness.

In an embodiment, the circuit layer may include a transistor layer and an insulating layer arranged on the transistor layer, and the first auxiliary electrode may be arranged on the insulating layer.

### BRIEF DESCRIPTION OF THE DRAWINGS

The above and other aspects, features, and advantages of certain embodiments of the disclosure will be more apparent from the following description taken in conjunction with the accompanying drawings in which:

FIG. 1 is a schematic perspective view of a display device according to an embodiment;

FIG. 2 is a schematic cross-sectional view of a display panel according to an embodiment;

FIG. 3 is a schematic plan view of a display panel according to an embodiment;

FIG. 4 is a schematic diagram of an equivalent circuit of a pixel according to an embodiment;

FIG. 5 is a plan view of an electrode layer located in one pixel of a display device according to an embodiment and a line arranged around the electrode layer;

FIG. 6 is a cross-sectional view of a display module according to an embodiment;

FIG. 7 is a cross-sectional view of a display panel according to an embodiment;

FIG. 8 is a plan view of a display panel corresponding to a hole area according to an embodiment;

FIG. 9 is a cross-sectional view of a display panel corresponding to a hole area according to an embodiment;

FIGS. 10 to 13 are cross-sectional views corresponding to a step of a method of manufacturing a display device according to an embodiment;

FIGS. 14 to 16 are photographs of a cross-section of an auxiliary electrode of a display panel according to an embodiment;

FIGS. 17A and 17B are photographs showing a phenomenon of pixel brightness unevenness that occurs in case that a thickness of an auxiliary electrode of a display panel is out of a certain range;

FIG. 18A is a photograph showing brightness and FIG. 18B shows brightness contour map of a display device according to an embodiment;

FIGS. 19 to 21 are tables showing the results of evaluating the characteristics of a display panel according to normal processing and overprocessing during processing of an organic layer hole of the display panel DP according to an embodiment;

FIG. 22 is a view for explaining an electronic device to which a display device according to an embodiment is applied;

FIG. 23 is a view for explaining another electronic device to which a display device according to an embodiment is applied;

FIGS. 24 and 25 are views for explaining another electronic device to which a display device according to an embodiment is applied; and

FIG. 26 is a view for explaining another electronic device to which a display device according to an embodiment is applied.

### DETAILED DESCRIPTION

As the disclosure allows for various changes and numerous embodiments, certain embodiments will be illustrated in the drawings and described in detail in the written description. Effects and features of the disclosure and methods of achieving the same will be apparent with reference to embodiments and drawings described below in detail. The disclosure may, however, be embodied in many different forms and should not be construed as being limited to the embodiments set forth herein.

In the following embodiments, the terms “first,” “second,” and the like are not used in a restrictive sense and are used to distinguish one element from another.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

In the embodiments disclosed below, when a part such as a unit, area, or component is said to be located on another part, it includes not only the case where the part is directly located on top of the another part, but also the case where other units, areas, components, etc. are interposed therebetween.

In the following embodiments, the terms, such as “connected” or “coupled” do not necessarily mean “two members being directly and/or fixedly connected or coupled,” unless otherwise specified within the context, and do not exclude the intervention of other members between the two members.

Sizes of elements in the drawings may be exaggerated for convenience of explanation. In other words, since sizes and thicknesses of components in the drawings are arbitrarily illustrated for convenience of explanation, the following embodiments are not limited thereto.

In this specification, “a region/portion corresponding to another region/portion” means “overlapping each other” and is not limited to having the same area and/or the same shape.

The disclosure will now be described more fully with reference to the accompanying drawings, in which preferred embodiments of the disclosure are shown. In description with reference to the drawings, the same or like elements will be given the same reference numeral, and a redundant description will be omitted.

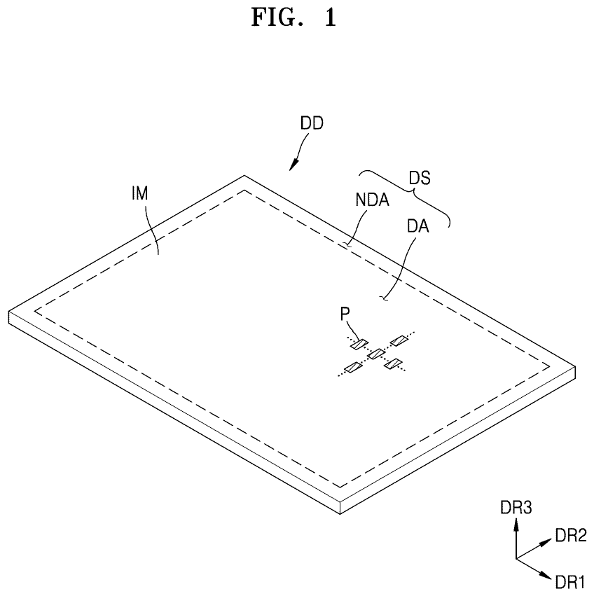

FIG. 1 is a schematic perspective view of a display device according to an embodiment.

Referring to FIG. 1, a display device DD according to an embodiment may be a device that is activated according to an electrical signal.

The display device DD according to an embodiment may include a display surface defined in a first direction DR1 and a second direction DR2 crossing the first direction DR1. Images generated in the display device DD may be provided to a user through the display surface.

Hereinafter, a direction crossing substantially perpendicular to the plane (display surface) defined by the first direction DR1 and the second direction DR2 may be defined as a third direction DR3. The third direction DR3 may be a reference for distinguishing a front surface (upper surface) and a rear surface (lower surface) of each member. In this specification, “in a plan view” may be defined as a state viewed in the third direction DR3 (i.e., thickness direction of the display device DD).

The display device DD according to an embodiment may include a display area DA and a non-display area NDA outside the display area DA. In FIG. 1, the display area DA is depicted as having a roughly rectangular shape, but the disclosure is not limited thereto. The display area DA may be formed in various shapes, such as circular, elliptical, and polygonal shapes.

The display area DA may be a part where an image is displayed, and a plurality of pixels P may be arranged in the display area DA. A “pixel” as used herein may refer to a “sub-pixel.” The pixels P may each include a light-emitting element, such as an organic light-emitting diode (OLED). The pixels P may each emit, for example, red light, green light, blue light, or white light.

The display area DA may provide a certain image through light emitted from the pixels P. The pixel P as used herein may be defined as an emission area where light of any one of red color, green color, blue color, or white color is emitted, as described above.

The non-display area NDA may be an area in which the pixels P are not arranged, and thus may be an area where an image is not displayed. Power supply lines configured to drive the pixels P, a terminal portion to which a printed circuit board or a driver integrated circuit (IC) including a driving circuit is connected, and the like may be arranged in the non-display area NDA.

Hereinafter, an organic light-emitting display device will be described as an example of the display device DD according to an embodiment. However, the display device DD according to an embodiment is not limited to this. The display device DD according to an embodiment may be a display device, such as an inorganic light-emitting display device (or inorganic electroluminescent (EL) display device) or a quantum dot light-emitting display device. For example, an emission layer included in the light-emitting element arranged in the display device DD may include an organic material or an inorganic material. Quantum dots may be positioned on a path of light emitted from the emission layer.

In addition, the display device 1 according to an embodiment may be applied to portable electronic devices, such as mobile phones, smartphones, tablet personal computers (PCs), mobile communication terminals, electronic organizers, e-books, portable multimedia players (PMPs), navigation systems, and ultra mobile PCs (UMPCs). Also, the display device DD according to an embodiment may be applied to various products, such as televisions, laptops, monitors, billboards, and Internet of things (IoT) devices. The display device DD according to an embodiment may also be applied to wearable devices, such as smart watches, watch phones, glasses-type displays, and head mounted displays (HMDs). The display device DD according to an embodiment may also be used in dashboards of automobiles, center information displays (CIDs) on the center fascia or dashboards of automobiles, room mirror displays replacing side mirrors of automobiles, and display screens on the rear sides of front seats to serve as entertainment devices for backseat passengers of automobiles.

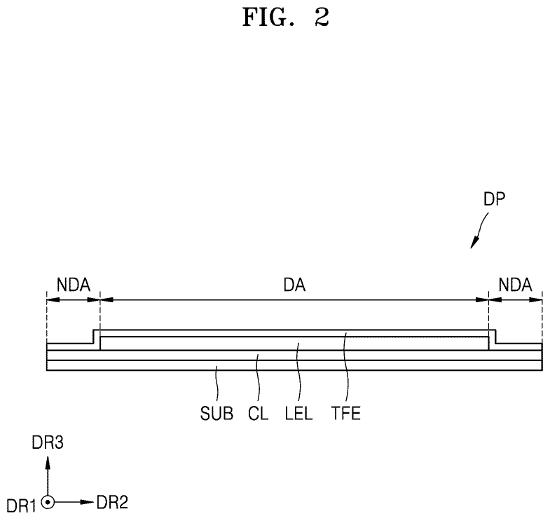

FIG. 2 is a schematic cross-sectional view of a display panel according to an embodiment.

Referring to FIG. 2, a display panel DP may include a base substrate BS, a circuit layer CL, a light-emitting element layer LEL, and an encapsulation layer TFE.

The base substrate BS may include a display area DA and a non-display area NDA. The base substrate BS may provide a base surface on which the circuit layer CL is arranged. The base substrate BS may be a rigid substrate or, without limitation, a flexible substrate. The base substrate BS may provide a base surface parallel to the plane defined by the first direction DR1 and the second direction DR2, and the circuit layer CL, the light-emitting element layer LEL, and the encapsulation layer TFE may be sequentially arranged on the base surface of the base substrate BS. In some embodiments, the third direction DR3 described above may be a direction perpendicular to the base surface of the base substrate BS, and the circuit layer CL, the light-emitting element layer LEL, and the encapsulation layer TFE may be sequentially arranged along the third direction DR3.

The circuit layer CL may be arranged on the base substrate BS. The circuit layer CL may include driving elements, signal lines, and signal pads. The light-emitting element layer LEL may include light-emitting elements arranged to overlap the display area DA. The light-emitting elements of the light-emitting element layer LEL may be electrically connected to the driving elements of the circuit layer CL, and may provide source light through the display area DA according to signals from the driving elements.

The encapsulation layer TFE may be arranged on the light-emitting element layer LEL to encapsulate the light-emitting elements. The encapsulation layer TFE may include a plurality of thin films. The thin films of the encapsulation layer TFE may be arranged to improve optical efficiency or protect the light-emitting elements.

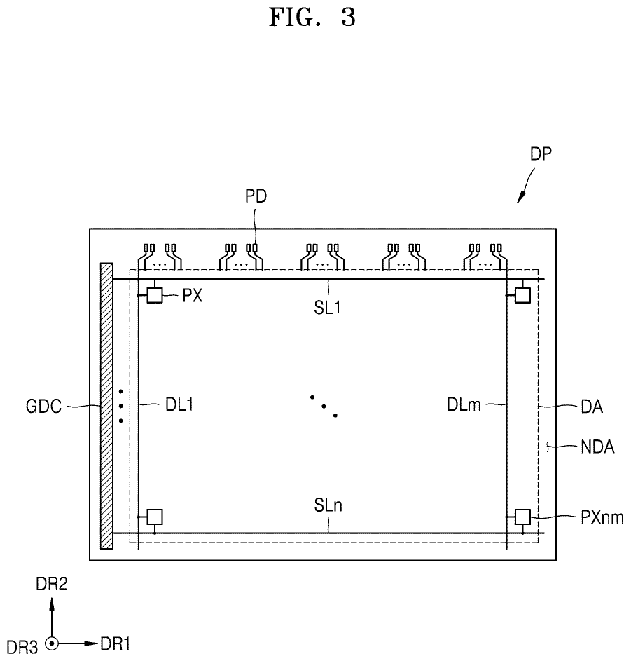

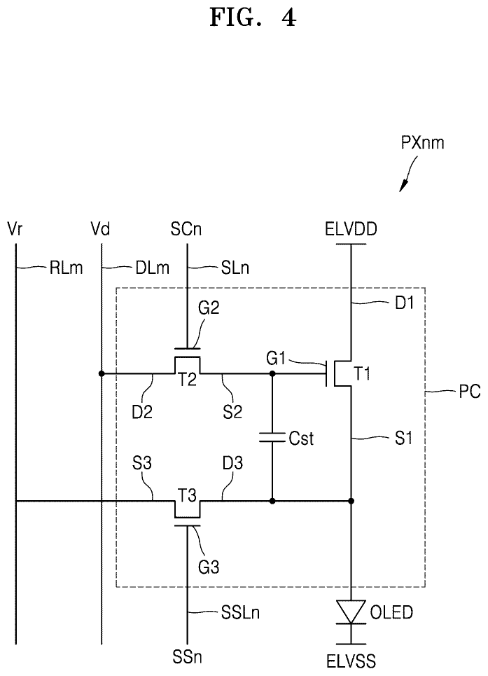

FIG. 3 is a schematic plan view of a display panel according to an embodiment. FIG. 4 is a schematic diagram of an equivalent circuit of a pixel according to an embodiment.

Referring to FIG. 3, the display panel DP may include pixels PX11 to PXnm arranged in the display area DA and signal lines SL1 to SLn, DL1 to DLm electrically connected to the pixels PX11 to PXnm. The display panel DP may include a driving circuit GDC and pads PD arranged in the non-display area NDA.

Each of the pixels PX11 to PXnm may include a light-emitting element to be explained later, and a pixel driving circuit including a plurality of transistors (e.g., a switching transistor, a driving transistor, and the like) and a capacitor connected to the light-emitting element. Each of the pixels PX11 to PXnm may emit light in response to an electrical signal applied to the pixel. FIG. 3 illustrates an example of the pixels PX11 to PXnm arranged in a matrix form, but the arrangement of the pixels PX11 to PXnm is not limited thereto.

The signal lines SL1 to SLn and DL1 to DLm may include scan lines SL1 to SLn and data lines DL1 to DLm. Each of the pixels PX11 to PXnm may be connected to a corresponding scan line among the scan lines SL1 to SLn and a corresponding data line among the data lines DL1 to DLm. More types of signal lines may be arranged on the display panel DP depending on the configuration of the pixel driving circuit of the pixels PX11 to PXnm.

The driving circuit GDC may include a gate driving circuit. The gate driving circuit may generate gate signals and sequentially output the gate signals to the scan lines SL1 to SLn. The gate driving circuit may further output another control signal to the pixel driving circuit of the pixels PX11 to PXnm.

The driving circuit GDC and the corresponding pixel PX11 to PXnm according to an embodiment may include a plurality of thin film transistors formed through a low temperature polycrystalline silicon (LTPS) process, a low temperature polycrystalline oxide (LTPO) process, or an oxide semiconductor process.

The pads PDs may be arranged along one direction in the non-display area NDA. The pads PD may be parts that are connected to a circuit board. The pads PD may each be connected to a corresponding signal line among the signal lines SL1 to SLn and DL1 to DLm and may be electrically connected to a corresponding pixel through the signal line. The pads PD may have an integral shape with the signal lines SL1 to SLn and DL1 to DLm. However, without being limited thereto, the pads PD may be arranged on a different layer from the signal lines SL1 to SLn and DL1 to DLm and connected through contact holes.

FIG. 4 illustrates an example of a pixel PXnm connected to an n-th scan line SLn, an n-th sensing line SSLn, an m-th data line DLm, and an m-th reference line RLm. Referring to FIG. 4, a pixel PXnm may include a pixel circuit PC and a light-emitting element LED connected to the pixel circuit PC.

The pixel circuit PC may include a plurality of transistors T1, T2, and T3 and a capacitor Cst. The plurality of transistors T1, T2, and T3 may include a first transistor T1 (or a driving transistor), a second transistor T2 (or a switching transistor), and a third transistor T3 (or a sensing transistor). Each of the first to third transistors T1, T2, and T3 may be a thin film transistor.

The first to third transistors T1, T2, and T3 may be NMOS transistors, but are not limited thereto, and may be PMOS transistors. The first to third transistors T1, T2, and T3 may each include a source S1, S2, S3, a drain D1, D2, D3, and a gate G1, G2, G3.

The light-emitting element LED may be an organic light-emitting diode that includes an anode (or a first electrode) and a cathode (or a second electrode). The anode of the light-emitting element LED may receive a first voltage ELVDD through the driving transistor T1, and the cathode of the light-emitting element LED may receive a second voltage ELVSS. The light-emitting element LED may emit light by receiving the first voltage ELVDD and the second voltage ELVSS.

The driving transistor T1 may include a drain D1 receiving the first voltage ELVDD, a source S1 connected to the anode of the light-emitting element LED, and a gate G1 connected to the capacitor Cst. The driving transistor T1 may control a driving current flowing to the light-emitting element LED from the first voltage ELVDD, in response to a voltage value stored in the capacitor Cst.

The switch transistor T2 may include a drain D2 connected to the m-th data line DLm, a source S2 connected to the capacitor Cst, and a gate G2 receiving an n-th write scan signal SCn. The m-th data line DLm may receive a data voltage Vd and a data voltage for sensing. The switch transistor T2 may transmit the data voltage Vd input from the m-th data line DLm to the driving transistor T1, in response to a switching voltage input from the n-th write scan signal SCn.

The sensing transistor T3 may include a source S3 connected to the m-th reference line RLm, a drain D3 connected to the anode of the light-emitting element LED, and a gate G3 receiving an n-th sampling scan signal SSn. The m-th reference line RLm may receive a reference voltage Vr.

The capacitor Cst may be connected to the gate G1 of the driving transistor T1 and the anode of the light-emitting element LED. The capacitor Cst may include a first capacitor electrode connected to the gate G1 of the driving transistor T1 and a second capacitor electrode connected to the anode of the light-emitting element LED. The capacitor Cst may store a voltage corresponding to a difference between a voltage received from the switch transistor T2 and the first voltage ELVDD.

In some embodiments, the equivalent circuit of the pixel PXnm is not limited to the equivalent circuit illustrated in FIG. 4. In another embodiment, the equivalent circuit of the pixel PXnm may be implemented in various forms to emit light from the light-emitting element LED.

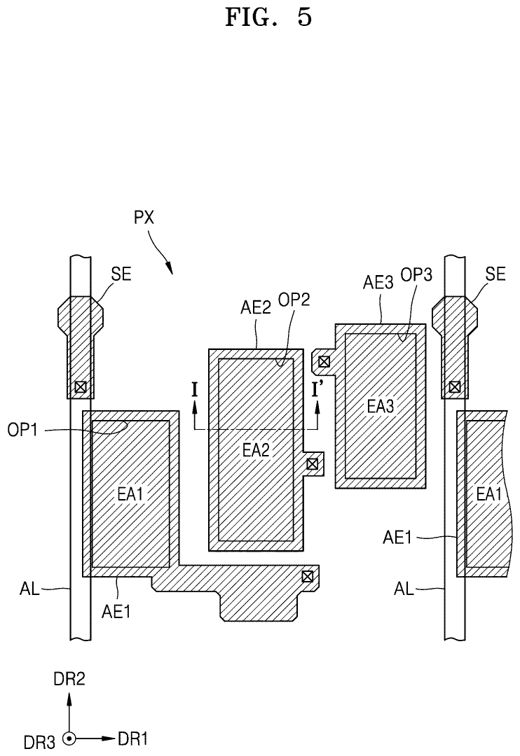

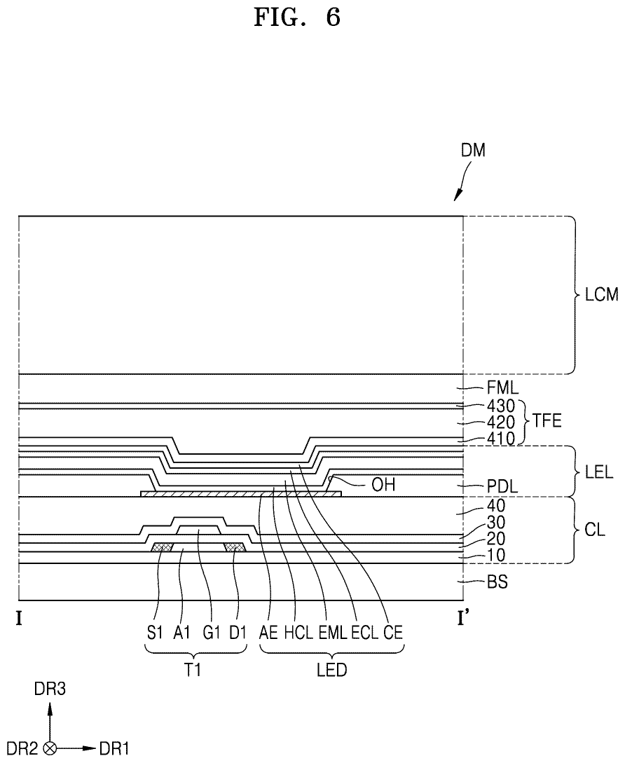

FIG. 5 is a plan view of an electrode layer located in one pixel of a display device DD according to an embodiment and a line arranged around the electrode layer. FIG. 6 is a cross-sectional view of a display module DM according to an embodiment.

A display device DD according to an embodiment may include a plurality of pixels PX configured to display an image.

Each pixel PXnm (see FIG. 3) of the display panel DP may include sub-pixels. FIG. 5 illustrates some pixels PX among the pixels PXnm (see FIG. 3), and hereinafter, each configuration of the pixels will be described based on one pixel PX (hereinafter, referred to as a pixel), and the same may be equally applied to other pixels.

The plurality of pixels PX may be arranged approximately in a matrix form, but is not limited thereto, and may be arranged repeatedly according to a certain rule.

Each pixel PX may include a plurality of sub-pixels PX1, PX2, and PX3. The plurality of sub-pixels PX1, PX2, and PX3 included in each pixel PX may emit light of different colors. For example, the plurality of sub-pixels PX1, PX2, and PX3 may display primary colors, such as red, green, and blue. Various colors may be displayed by combining various brightness of different primary colors displayed by the plurality of sub-pixels PX1, PX2, and PX3.

The light-emitting element LED of the pixel PX may include pixel electrodes AE1, AE2, and AE3 arranged on a base substrate BS (see FIG. 2). The pixel electrodes AE1, AE2, and AE3 may be arranged spaced apart from one another in a plan view. The respective pixel electrodes AE1, AE2, and AE3 included in the single pixel PX may correspond to the sub-pixels constituting the pixel PX.

A pixel defining layer PDL may be arranged on the pixel electrodes AE1, AE2, and AE3. The pixel defining layer PDL may be formed to correspond to each of the pixel electrodes AE1, AE2, and AE3, and emission openings OP1, OP2, and OP3 that expose at least portions of the pixel electrodes AE1, AE2, and AE3 may be defined in the pixel defining layer PDL.

The display area DA of the display panel DP may be divided into emission areas EA1, EA2, and EA3 corresponding to the sub-pixels and a non-emission area NEA surrounding the emission areas.

The pixel defining layer PDL may define the emission areas EA1, EA2, and EA3 and the non-emission area NEA. Areas of the pixel electrodes AE1, AE2, and AE3 exposed by the emission openings OP1, OP2, and OP3 of the pixel defining layer PDL may be defined as the emission areas EA1, EA2, and EA3, and an area that does not overlap the emission openings OP1, OP2, and OP3 of the pixel defining layer PDL may be defined as the non-emission area NEA.

To explain this from another perspective, an emission layer may be arranged inside a first emission opening OP1, a second emission opening OP2, and a third emission opening OP3, and the first emission opening OP1, the second emission opening OP2, and the third emission opening OP3 may correspond to a first emission area EA1, a second emission area EA2, and a third emission area EA3, respectively.

The emission areas EA1, EA2, and EA3 may be separated by the non-emission area NEA arranged between the emission areas EA1, EA2, and EA3. The emission areas EA1, EA2, and EA3 may correspond to areas where light emitted from the light-emitting element of the pixel PX is output.

The first to third emission areas EA1, EA2, and EA3 may be distinguished according to colors of light emitted toward the outside of the display device DD.

The first emission area EA1 may correspond to an area where a first color of light is emitted, the second emission area EA2 may correspond to an area where a second color of light is emitted, and the third emission area EA3 may correspond to an area where a third color of light is emitted. In an embodiment, the first to third colors of light may be different colors. For example, the first color of light may be green light, the second color of light may be red light, and the third color of light may be blue light. However, embodiments are not limited to this.

The non-emission area NEA may set a boundary among the first to third emission areas EA1, EA2, and EA3 and may suppress color mixing among the first to third emission areas EA1, EA2, and EA3.

The first to third emission areas EA1, EA2, and EA3 may have a certain arrangement in the display area DA. The second emission area EA2 and the third emission area EA3 may be arranged in a plan view in the first direction DR1. A center of the second emission area EA2 and a center of the third emission area EA3 may be arranged in parallel in the first direction DR1. The first emission area EA3 may be positioned between the second emission area EA2 and the third emission area EA3 in a plan view.

In some embodiments, the arrangement of the first to third emission areas EA1, EA2, and EA3 illustrated in FIG. 5 is exemplary and is not limited thereto, and the arrangement of the emission areas may vary depending on the design of the display device DD.

The shape and size of the first to third emission areas EA1, EA2, EA3 may be designed in various ways by considering light emission efficiency of the colors output through the corresponding emission areas, and are not limited to the embodiment illustrated in FIG. 5.

The display panel DP may be arranged on the base substrate BS (see FIG. 2) and may include an auxiliary line AL to which the second voltage ELVSS (see FIG. 4) is applied. The auxiliary line AL may be arranged to overlap the non-emission area NEA. The auxiliary line AL may be arranged at a different layer from the pixel electrodes AE1, AE2, and AE3. However, without being limited thereto, the auxiliary line AL may be arranged at the same layer as the pixel electrodes AE1, AE2, and AE3.

The auxiliary line AL may have a line shape extending along the first direction DR1 or the second direction DR2, and may also have a grid shape surrounding the pixel electrodes constituting one pixel. The auxiliary line AL may have various shapes, without being limited to any embodiment, as long as the auxiliary line AL may apply the second voltage ELVSS to each pixel PXnm (see FIG. 3).

The display panel DP may include an auxiliary electrode SE that is arranged on the base substrate BS (see FIG. 2) and electrically connected to the auxiliary line AL. In an embodiment, the auxiliary electrode SE may be arranged on a different layer from the auxiliary line AL and may be connected to the auxiliary line AL through a contact hole. At least a portion of the auxiliary electrode SE may be exposed by an opening S-OP defined in the pixel defining layer PDL. The at least partially exposed auxiliary electrode SE may be electrically connected to a counter electrode of the light-emitting element, and may apply the second voltage ELVSS (see FIG. 4) to the counter electrode.

The auxiliary electrode SE may receive different voltages from the pixel electrodes AE1, AE2, and AE3. In an embodiment, the pixel electrodes AE1, AE2, and AE3 may receive the first voltage ELVDD (see FIG. 4), and the auxiliary electrode SE may receive the second voltage ELVSS (see FIG. 4).

The auxiliary electrode SE may be arranged spaced apart from the pixel electrodes AE1, AE2, and AE3 on the plane. In an embodiment, the auxiliary electrode SE may be arranged spaced apart from the pixel electrodes AE1, AE2, and AE3 at the same layer.

The auxiliary electrode SE may have an island shape spaced apart from the pixel electrodes AE1, AE2, and AE3. However, without being limited thereto, the auxiliary electrode SE may have a line shape extending along one direction, like the auxiliary line AL. The shape, size, and the like of the auxiliary electrode SE may vary depending on the design of the display panel DP. For example, the auxiliary electrode SE may have a rectangular shape in a plan view, or may have a circular shape. Alternatively, the auxiliary electrode SE may include a relatively wide portion and a relatively narrow portion in a plan view, as illustrated in FIG. 5. The opening S-OP defined in the pixel defining layer PDL may have a shape corresponding to the shape of the auxiliary electrode SE.

The auxiliary electrode SE may be arranged to correspond to each pixel PX as illustrated in FIG. 5. However, the auxiliary electrode SE is not limited thereto, and may be arranged for each of the plurality of pixels or for each sub-pixel, and the arrangement design of the auxiliary electrode SE may vary.

A display module DM according to an embodiment may include a display panel DP and a light control member LCM.

The light control member LCM may be arranged on the display panel DP. The light control member LCM may be arranged on the display panel DP and then coupled to the display panel DP through a bonding process using a sealing member. However, without limitation, the light control member LCM may be arranged directly on the display panel DP. In this specification, “being formed through a continuous process without arranging a separate adhesive layer or adhesive member” may be expressed as “being directly arranged.” For example, the expression “the light control member LCM being directly arranged on the display panel DP” may indicate that the display panel DP is formed first and the configuration of the light control member LCM is formed on the base surface provided by the display panel DP through a continuous process.

The display module DM according to an embodiment may include a base substrate BS, a circuit layer CL arranged on the base substrate BS, a light-emitting element layer LEL arranged on the circuit layer CL, and an encapsulation layer TFE arranged on the light-emitting element layer LEL. In some embodiments, the base substrate BS, the circuit layer CL, the light-emitting element layer LEL, and the encapsulation layer TFE may be the components of the display panel DP described above in FIG. 2.

The light control member LCM may include light control patterns that are formed to change optical properties of source light emitted from the display panel DP. The light control member LCM may optionally convert a wavelength or color of the source light, or transmit the source light. The light control member LCM may control color purity or color gamut of light emitted from the display device DD and suppress reflection of external light incident from the outside of the display device DD.

The base substrate BS may provide a base surface on which the circuit layer CL is arranged. The base substrate BS may include a glass material or a resin material. The glass material may include transparent glass with silicon oxide as a main component. The resin material may include a polymer resin, such as polyethersulfone, polyacrylate, polyether imide, polyethylene naphthalate, polyethylene terephthalate, polyphenylene sulfide, polyarylate, polyimide, polycarbonate, cellulose triacetate, cellulose acetate propionate, or the like. In case that the base substrate BS includes the polymer resin, the display device DD may have flexible, rollable, and bendable characteristics. However, the material of the base substrate BS is not limited to the example.

The circuit layer CL may be arranged on the base substrate BS. The circuit layer CL may include insulating layers, transistors each including a semiconductor pattern, circuit lines connected to the transistors, and conductive patterns.

The circuit layer CL may include a transistor T1 as a circuit element. The configuration of the circuit layer CL may vary depending on the design of the driving circuit of the pixels PX11 to PXnm (see FIG. 3), and FIG. 6 illustrates an example of a driving transistor T1. The arrangement relationship of an active A1, a source S1, a drain D1, and a gate G1 that constitute the transistor T1 is illustrated as an example. The active A1, the source S1, and the drain D1 may be areas that are distinguished according to doping concentration or conductivity of the semiconductor pattern.

The circuit layer CL may include a buffer layer 10, a first insulating layer 20, a second insulating layer 30, and a third insulating layer 40 that are arranged on the base substrate BS. For example, the buffer layer 10, the first insulating layer 20, and the second insulating layer 30 may be inorganic layers, and the third insulating layer 40 may be an organic layer.

A light-emitting element layer LEL may be arranged on the circuit layer CL. The light-emitting element layer LEL may include a plurality of light-emitting elements LED each of which includes a first electrode AE, an emission layer EML, and a second electrode CE sequentially laminated to emit light, and a pixel defining layer PDL that defines pixels. The plurality of light-emitting elements LED of the light-emitting element layer LEL may be arranged in the display area DA.

In an embodiment disclosed herein, the light-emitting element layer LEL may include an organic light-emitting diode as the light-emitting element. In an embodiment, the light-emitting element may include a quantum dot light-emitting diode. For example, the emission layer EML included in the light-emitting element LED may include an organic light-emitting material as a light-emitting material, or may include quantum dots as the light-emitting material. Alternatively, the light-emitting element layer LEL according to an embodiment may include an ultra-small light-emitting element as the light-emitting element. The ultra-small light-emitting element may include, for example, a micro LED element and/or a nano LED element. The ultra-small light-emitting device may have length and width ranging from several hundred nanometers to several hundred micrometers.

A first opening OH may be defined in the pixel defining layer PDL. The first opening OH in the pixel defining layer PDL may expose at least a portion of the first electrode AE. In an embodiment disclosed herein, the first opening OH may be defined in the first emission area EA1.

To explain this from another perspective, the pixel defining layer PDL may be arranged on the plurality of first electrodes AE, to cover edges of the plurality of first electrodes AE while exposing central portions of the plurality of first electrodes AE. The pixel defining layer PDL may define the emission area EA. In some embodiments, the emission area EA may be defined by the opening of the pixel defining layer PDL. The pixel defining layer PDL may include an organic insulating material, for example, an acrylic material or benzocyclobutene (BCB).

The first electrode AE may be arranged on the fourth insulating layer 30. The first electrode AE may be directly or indirectly connected to the transistor T1, and a connection structure between the first electrode AE and the transistor T1 is not illustrated in FIG. 6.

Referring to FIGS. 5 and 6 together, a hole control layer HCL, an emission layer EML, and an electron control layer ECL may overlap at least the emission area EA. The hole control layer HCL, the emission layer EML, the electron control layer ECL, and the second electrode CE may be commonly arranged in the first to third emission areas EA1, EA2, and EA3. Each of the hole control layer HCL, the emission layer EML, the electron control layer ECL, and the second electrode CE that overlap the first to third emission areas EA1, EA2, and EA3 may have an integral shape. However, without being limited thereto, at least one of the hole control layer HCL, the emission layer EML, and the electron control layer ECL may be formed separately in each of the first to third emission areas EA1, EA2, and EA3.

The hole control layer HCL may include a hole transport layer and may further include a hole injection layer. The emission layer EML may generate blue light as source light. Blue light may include light with a wavelength of 410 nm to 480 nm. An emission spectrum of blue light may have a maximum peak in the range of 440 nm to 460 nm. The electron control layer ECL may include an electron transport layer and may further include an electron injection layer.

The encapsulation layer TFE may be arranged on the second electrode CE. The encapsulation layer TFE may include at least one inorganic encapsulation layer and at least one organic encapsulation layer. The encapsulation layer TFE may have a multilayer structure in a repeated arrangement of inorganic/organic layers. In an embodiment, FIG. 6 illustrates that the encapsulation layer TFE includes a first inorganic encapsulation layer 410, a second inorganic encapsulation layer 430, and an organic encapsulation layer 420 between the first inorganic encapsulation layer 410 and the second inorganic encapsulation layer 430. The first and second inorganic encapsulation layers 410 and 430 may each include at least one inorganic insulating material. The inorganic insulating material may include aluminum oxide, titanium oxide, tantalum oxide, hafnium oxide, zinc oxide, silicon oxide, silicon nitride, and/or silicon oxynitride. The encapsulation layer TFE may protect the light-emitting element layer LEL from foreign substances, such as moisture, oxygen, and dust particles.

The light control member LCM may be arranged on the encapsulation layer TFE. The light control member LCM may include a light control layer (not shown), a color filter layer (not shown), and a base layer (not shown).

A light control pattern (not shown) may be arranged on the light control member LCM. The light control pattern may change optical properties of source light. The light control pattern may include quantum dots to change the optical properties of the source light.

The quantum dots may control the color of light they emit depending on particle sizes, and thus have various emission colors, such as blue, red, and green.

In some embodiments, in case that the quantum dots have various emission colors, such as blue, red, and green, quantum dots with different emission colors may have different materials for cores.

The light control pattern may further include a scatterer. The light control pattern may include quantum dots that convert blue light into green light, and a scatterer that scatters light.

The color filter layer may be arranged on the light control layer. The color filter layer may include at least one color filter (not shown). Color filters may transmit light in a specific wavelength range and block light outside the corresponding wavelength range.

In an embodiment, the display panel DP may further include a base layer arranged on the color filter layer. The base layer may be a member that provides a reference surface on which the color filter layer and the light control layer are arranged. The base layer may be a glass substrate, a metal substrate, a plastic substrate, or the like. However, embodiments are not limited thereto, and the base layer may be an inorganic layer, an organic layer, or a composite material layer.

The display panel DP according to an embodiment may include a lower panel including the light-emitting element layer LEL and an upper panel including the light control layer and the color filter layer, and in an embodiment, a filling layer FML may be arranged between the lower panel and the upper panel. In an embodiment, the filling layer FML may be filled between the light-emitting element layer LEL and the light control layer CCL. The filling layer FML may be arranged directly on the encapsulation layer TFE, and a first barrier layer (not shown) included in the light control layer may be arranged directly on the filling layer FML. A lower surface of the filling layer FML may be in contact with an upper surface of the encapsulation layer TFE, and an upper surface of the filling layer FML may be in contact with a lower surface of the first barrier layer.

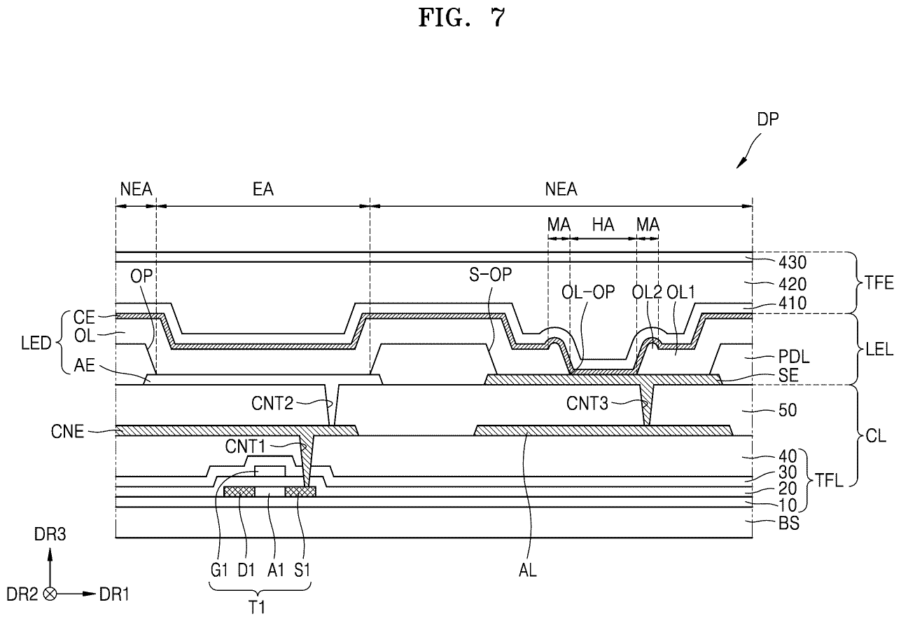

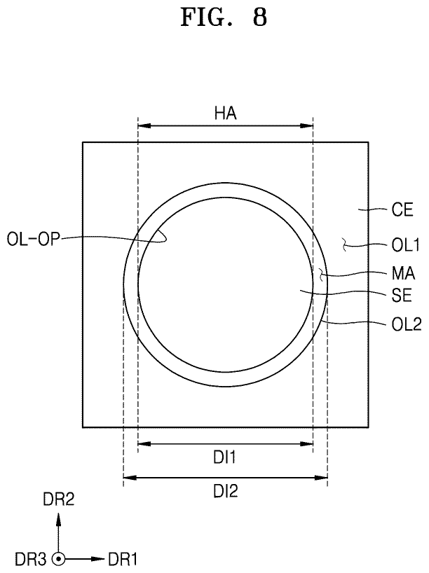

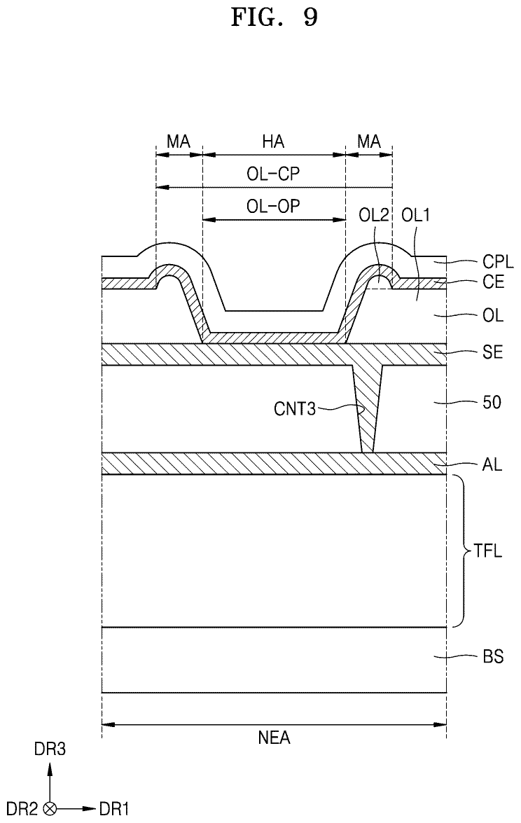

FIG. 7 is a cross-sectional view of a display panel according to an embodiment. FIG. 8 is a plan view of a display panel corresponding to a hole area according to an embodiment. FIG. 9 is a cross-sectional view of a display panel corresponding to a hole area according to an embodiment.

Referring to FIG. 7, the display panel DP may include a base substrate BS, a circuit layer CL, a light-emitting element layer LEL, and an encapsulation layer TFE, and the above description may be equally applied. FIG. 7 illustrates an example of a cross-section of the light-emitting element LED corresponding to one of the emission areas EA described above and an auxiliary electrode SE adjacent to the light-emitting element LED.

At least one inorganic layer may be arranged on an upper surface of the base substrate BS. The inorganic layer may constitute a barrier layer and/or a buffer layer. FIG. 5 illustrates an example of an inorganic layer defined as the buffer layer 10. The buffer layer 10 may improve bonding strength between the base substrate BS and the semiconductor pattern of the circuit layer CL. The buffer layer 10 may include at least one of aluminum oxide, titanium oxide, silicon oxide, silicon nitride, silicon oxynitride, zirconium oxide, and hafnium oxide, but is not limited to the materials.

The semiconductor pattern of the circuit layer CL may be arranged on the buffer layer 10. The semiconductor pattern may include polysilicon. However, without being limited to this, the semiconductor pattern may include amorphous silicon or metal oxide.

The source S1, the active A1, and the drain D1 of the transistor T1 may be formed from the semiconductor pattern. The semiconductor pattern of the transistor T1 may be divided into a plurality of areas depending on the degree of conductivity. Among the plurality of areas of the semiconductor pattern, an area which is doped with the semiconductor pattern at a relatively high concentration and thus has relatively high conductivity may serve as an electrode or a signal line and may correspond to the source S1 or the drain D1 of the transistor T1. Among the plurality of areas of the semiconductor pattern, another area which is not doped with the semiconductor pattern, is doped with the semiconductor pattern at a relatively low concentration, or is not reduced may have relatively low conductivity, and the corresponding area may correspond to the active A1 of the transistor T1.

The circuit layer CL may include a plurality of transistors and a plurality of insulating layers that constitute the pixel circuit PC (see FIG. 4). FIG. 7 illustrates an example of a first transistor T1 and first to fourth insulating layers 20, 30, 40, and 50.

The circuit layer CL may include a plurality of transistors and a plurality of insulating layers that constitute the pixel circuit PC (see FIG. 4). FIG. 7 illustrates an example of a first transistor T1 and first to fourth insulating layers 20, 30, 40, and 50.

The first insulating layer 20 may cover the semiconductor pattern of the circuit layer CL. The gate G1 of the first transistor T1 may be arranged on the first insulating layer 20. The gate G1 may be a portion of a conductive pattern. The gate G1 may overlap the active A1. The gate G1 may function as a mask in a process of doping the semiconductor pattern. The second insulating layer 30 may be arranged on the first insulating layer 20 and may cover the gate G1. The third insulating layer 40 may be arranged on the second insulating layer 30.

In some embodiments, a layer which includes the buffer layer 10, the first to third insulating layers 20, 30, and 40, and the transistor (e.g., the first transistor T1 of FIG. 7) formed between the adjacent insulating layers may be defined as a transistor layer TFL.

A connection electrode CNE may be arranged between the first transistor T1 and the light-emitting element LED, to connect the first transistor T1 and the light-emitting element LED. The connection electrode CNE may be arranged on the third insulating layer 40, and may be connected to the source S1 of the first transistor T1 through a first contact hole CNT1, which is formed through the first and second insulating layers 20 and 30.

An auxiliary line AL may be arranged on the third insulating layer 40. In an embodiment, the auxiliary line AL may be arranged at the same layer as the connection electrode CNE. The auxiliary line AL may be electrically connected to a power line, through which the second voltage ELVSS (see FIG. 4) is applied, thereby applying the second voltage ELVSS.

The fourth insulating layer 50 may be arranged on the third insulating layer 40. The fourth insulating layer 50 may cover the connection electrode CNE and the auxiliary line AL. In an embodiment, the fourth insulating layer 50 may include an organic layer. The fourth insulating layer 50 including the organic layer may provide a flat upper surface. However, embodiments are not limited to this.

The light-emitting element layer LEL may be arranged on the circuit layer CL. The light-emitting element layer LEL may include a plurality of light-emitting elements LED (see FIG. 6) and the pixel defining layer PDL, and FIG. 7 illustrates an example of a cross-section corresponding to one light-emitting element LED. The light-emitting element LED may include a first electrode AE (or a pixel electrode), an organic layer OL, and a second electrode CE (or a counter electrode). Here, the first electrode AE may correspond to any one of the pixel electrodes AE1, AE2, and AE3 described above.

The first electrode AE may be arranged in a first area on the base substrate BS. In an embodiment, the first electrode AE may be arranged on the fourth insulating layer 50 of the circuit layer CL. The first electrode AE may be connected to the connection electrode CNE through a second contact hole CNT2 which is formed through the fourth insulating layer 50. The first electrode AE may be connected to the first transistor T1 via the connection electrode CNE.

The pixel defining layer PDL may be arranged on the fourth insulating layer 50. The pixel defining layer PDL may include an emission opening OP which is defined to expose a portion of the first electrode AE. The pixel defining layer PDL may cover a portion of an upper surface of the first electrode AE. The portion of the first electrode AE exposed through the emission opening OP of the pixel defining layer PDL may correspond to the emission area EA.

The pixel defining layer PDL may include a light absorbing material or may have a certain color. For example, the pixel defining layer PDL may include a base resin and a black pigment and/or black dye mixed in the base resin.

The organic layer OL may include an emission layer EML (see FIG. 6) and a functional layer arranged between the first electrode AE and the second electrode CE opposing each other. The functional layer may include, for example, a hole control layer HCL (see FIG. 6) and an electron control layer ECL (see FIG. 6).

The second electrode CE may oppose the first electrode AE and may be arranged on the organic layer OL. The second electrode CE may be a common layer provided in common to a plurality of pixels and may overlap the emission area EA and the non-emission area NEA. A common voltage may be applied to the second electrode CE.

The second electrode CE may include a conductive material having a low work function. For example, the second electrode CE may include a (semi) transparent layer which includes silver (Ag), magnesium (Mg), aluminum AL, platinum (Pt), palladium PD, gold (Au), nickel (Ni), neodymium (Nd), iridium (Ir), chromium (Cr), lithium (Li), calcium (Ca), or an alloy thereof. Alternatively, the second electrode CE may further include a layer, such as ITO, IZO, ZnO, or In₂O₃, on the (semi) transparent layer including the aforementioned material.

The second electrode CE may be formed by being deposited thinly to have light transmittance. The second electrode CE may have at least a certain thickness to suppress an IR drop phenomenon and allow light emission with uniform brightness by being in contact with an auxiliary electrode SE, as will be described later. Here, the IR drop, also known as a voltage drop, is a phenomenon where the voltage decreases as current flows through a conductor due to its resistance. For example, the thickness of the second electrode CE may range from 50 angstroms (Å) to 200 Å. In case that the thickness of the second electrode CE is less than 50 Å, the effect of suppressing the IR drop phenomenon may not be achieved even though the second electrode CE and the auxiliary electrode SE are in contact with each other. In case that the thickness of the second electrode CE exceeds 200 Å, the light transmittance of the second electrode CE may decrease, which may reduce light emission efficiency of the light-emitting element.

The auxiliary electrode SE may be arranged in a second area on the base substrate BS. In an embodiment, the auxiliary electrode SE may be arranged on the fourth insulating layer 50 of the circuit layer CL. The auxiliary electrode SE may be connected to the auxiliary line AL through a third contact hole CNT3 which is formed through the fourth insulating layer 50. The auxiliary electrode SE may receive the second voltage through the auxiliary line AL. However, without being limited thereto, the auxiliary electrode SE may be directly connected to a power line, which applies the second voltage, and may receive the second voltage.

The auxiliary electrode SE may be arranged at the same layer as the first electrode AE. In an embodiment, the auxiliary electrode SE and the first electrode AE may be directly disposed on the fourth insulating layer 50. The auxiliary electrode SE may be arranged in an island shape spaced apart from the first electrode AE in a plan view. However, without being limited to this, the auxiliary electrode SE may be arranged in a line shape extending in one direction in a plan view. For example, the auxiliary electrode SE may be arranged in a line shape extending along the second direction DR2, which is the extension direction of the auxiliary line AL. The shape of the auxiliary electrode SE is not limited to any embodiment as long as the auxiliary electrode SE is arranged spaced apart from the first electrode AE. As described above, the auxiliary electrode SE may have a rectangular shape in a plan view, or may have a circular shape.

In an embodiment, functional layers and emission layers included in the organic layer OL may be provided as a common layer which overlaps the emission area EA and the non-emission area NEA and has an integral shape. However, without being limited thereto, some of the functional layers and the emission layer included in the organic layer OL may be provided by being patterned inside the emission opening OP defined in the pixel defining layer PDL. At least some of the functional layers and the emission layer included in the organic layer OL may be patterned by a method, such as inkjet printing, and arranged inside the emission opening OP of the pixel defining layer PDL to overlap the emission area EA.

A portion of the organic layer OL may overlap the auxiliary electrode SE in a plan view. An opening S-OP exposing a portion of the auxiliary electrode SE may be defined in the pixel defining layer PDL, and a portion of the organic layer OL may be located inside the opening S-OP of the pixel defining layer PDL overlapping the auxiliary electrode SE. Therefore, the portion of the organic layer OL may be arranged between the auxiliary electrode SE and the second electrode CE.

An opening OL-OP may be defined in the organic layer OL. The opening OL-OP may be formed through the functional layers and the emission layer included in the organic layer OL and expose a portion of the auxiliary electrode SE. Here, the opening OL-OP may also be referred to as a hole of the organic layer. The portion of the auxiliary electrode SE exposed by the opening OL-OP of the organic layer OL may be defined as an opening area HA. The second electrode CE may be electrically connected to the auxiliary electrode SE through the opening area HA of the organic layer OL. In an embodiment, the second electrode CE may be directly connected to the auxiliary electrode SE through the opening OL-OP such that the organic layer OL is not disposed between the second electrode CE and the auxiliary electrode SE.

The second electrode CE may be provided as an electrode having relatively high light transmittance, such that light generated from the emission layer included in the organic layer OL is emitted toward a display surface DS (see FIG. 1) through the second electrode CE. For example, the second electrode CE may be configured as a transparent electrode or as an electrode having a thin thickness. In this instance, resistance of the second electrode CE may increase, which may cause the IR drop phenomenon. However, the second electrode CE may be brought into contact with the auxiliary electrode SE, which may reduce the resistance of the second electrode CE and suppress the IR drop phenomenon accordingly.

The organic layer OL may include a first portion OL1 which overlaps a portion of the auxiliary electrode SE and has a flat upper surface, and a second portion OL2 protruding from the first portion OL1 toward the encapsulation layer TFE. Hereinafter, the second portion OL2 may be referred to as a “protrusion OL2”. A portion, which is defined by an edge of the protrusion OL2 spaced from a center of the opening OL-OP, may be referred to as a contact pattern portion OL-CP. The protrusion OL2 may be arranged adjacent to the opening OL-OP formed through the organic layer OL.

The encapsulation layer TFE may be arranged on the light-emitting element layer LEL to encapsulate the light-emitting element layer LEL. The encapsulation layer TFE may include an inorganic layer and an organic layer. FIG. 7 illustrates an embodiment of the encapsulation layer TFE, which includes first and second inorganic encapsulation layers 410 and 430, and an organic encapsulation layer 420 arranged between the first and second inorganic encapsulation layers 410 and 430. The first inorganic encapsulation layer 410 may be arranged on the second electrode CE, and the organic encapsulation layer 420 and the second inorganic encapsulation layer 430 may be sequentially arranged on the first inorganic encapsulation layer 410.

FIG. 8 is a schematic plan view of the auxiliary electrode SE and the second electrode CE that are in contact with each other through the opening area HA. In FIG. 9, the configurations of the encapsulation layer TFE and the transistor layer TFL of FIG. 7 are omitted and the configurations of the display panel DP corresponding to the opening area HA are briefly illustrated.

Referring to FIGS. 7 to 9, the opening OL-OP may be defined through the organic layer OL, and the portion of the auxiliary electrode SE may be exposed through the opening OL-OP. The exposed portion of the auxiliary electrode SE may be defined as the opening area HA, and the second electrode CE may be electrically connected to the auxiliary electrode SE through the opening area HA.

The protrusion OL2 may be arranged adjacent to the opening OL-OP formed through the organic layer OL. The protrusion OL2 may be formed to surround the periphery of the opening OL-OP in a plan view. An area from an end of the opening OL-OP to an edge of the protrusion OL2 in a plan view may be defined as a protrusion area MA. The protrusion area MA may be adjacent to the opening area HA and may have a shape that surrounds the opening area HA in a plan view.

The opening area HA in which the opening OL-OP is defined may have a circular shape in a plan view, and the protrusion OL2 may surround the circular opening OL-OP.

The shape of the protrusion OL2 on the plane is not limited to the illustrated embodiment, and may have various shapes corresponding to the shape of the opening OL-OP.

The opening OL-OP and the protrusion OL2 surrounding the opening OL-OP may have a certain diameter in a plan view. The opening area HA in which the opening OL-OP is defined and the protrusion area MA in which the protrusion OL2 is arranged may be circular areas having a certain diameter in a plan view. The diameter of the opening OL-OP may be defined as a width of the opening OL-OP in the first direction DR1.

For example, the opening OL-OP may have a first diameter DI1. The edge of the protrusion OL2 may have a second diameter DI2. For example, a distance between edges of the protrusion OL2 passing through a center of the opening OL-OP may correspond to the second diameter DI2. In an embodiment, a diameter of the contact pattern portion OL-CP may correspond to the second diameter DI2. Here, the second diameter DI2 may be larger than the first diameter DI1.

The protrusion OL2 may include a curved surface on a cross section. In an embodiment, the curved surface of the protrusion OL2 may be formed to overlap the protrusion area MA. By virtue of the protrusion OL2, the thickness of a portion of the organic layer OL which overlaps the auxiliary electrode SE may be greater than the thickness of the organic layer OL which overlaps the first electrode AE.

The opening OL-OP may be formed through a laser drilling process to be described later. During the process of forming the opening OL-OP, a portion of the organic layer OL may be pushed in an outward direction of the opening OL-OP by a laser. During this process, the protrusion OL2 may be formed on the organic layer OL.

Referring to FIGS. 3 and 9 together, the display panel DP may include at least 200,000 to at least one million openings OL-OP in total. The display panel DP according to an embodiment may include auxiliary electrodes SE and openings OL-OP corresponding to the number of pixels PX. In an embodiment, the display panel DP may include about 200,000 to about one million openings OL-OP. In an embodiment, the display panel DP may include about 7 million to about 35 million pixels PX and may include about 200,000 to about one million openings OL-OP. In case that the number of openings OL-OP included in the display panel DP is less than about 200,000, a contact area between the second electrode CE and the auxiliary electrode SE may decrease, resulting in uneven brightness. In case that the number of openings OL-OP included in the display panel DP exceeds about one million, an aperture ratio of the display panel DP may decrease, resulting in decreased display efficiency of the display panel DP.

In some embodiments, referring to FIG. 9, the light-emitting element LED may further include a capping layer CPL arranged on the second electrode CE. The capping layer CPL may have a single-layer or multi-layer structure. The capping layer CPL may include an organic layer or an inorganic layer. For example, the inorganic layer of the capping layer CPL may include at least one of an alkali metal compound, such as LiF, an alkaline-earth metal compound, such as MgF2, silicon nitride, silicon oxynitride, or silicon oxide. The organic layer of the capping layer CPL may include α-NPD, NPB, TPD, m-MTDATA, Alq3, CuPc, TCTA, an epoxy resin, or an acrylate resin. However, the material of the capping layer CPL is not limited to the above examples.

Referring to FIGS. 8, 9, and 12 together, in the display panel DP according to an embodiment, the organic layer OL may further include an intermediate portion OL3. The intermediate portion OL3 may be adjacent to the opening OL-OP and may be positioned between a portion where the protrusion OL2 is arranged and the opening OL-OP. An area where the protrusion OL2 is arranged may be referred to as a protrusion area, and an area where the intermediate portion OL3 is arranged may be referred to as an intermediate area.

The intermediate portion OL3 may have a circular shape surrounding the opening OL-OP in a plan view. The intermediate portion OL3 may be a portion which is adjacent to the opening OL-OP and in which a slope of the organic layer OL is smaller than a slope of the portion where the protrusion OL2 is arranged. The organic layer OL may not be arranged in the opening OL-OP, may be arranged at a relatively gentle slope in the intermediate portion OL3, and may be arranged at a steep slope in the portion where the protrusion OL2 is arranged. The intermediate portion OL3 may be a portion where the organic layer OL partially remains without being completely removed because laser intensity at an edge portion is weaker than that at a central portion in a laser process to be described later. The thickness of the intermediate portion OL3 may be thinner than a thickness of another portion where the organic layer OL is arranged.

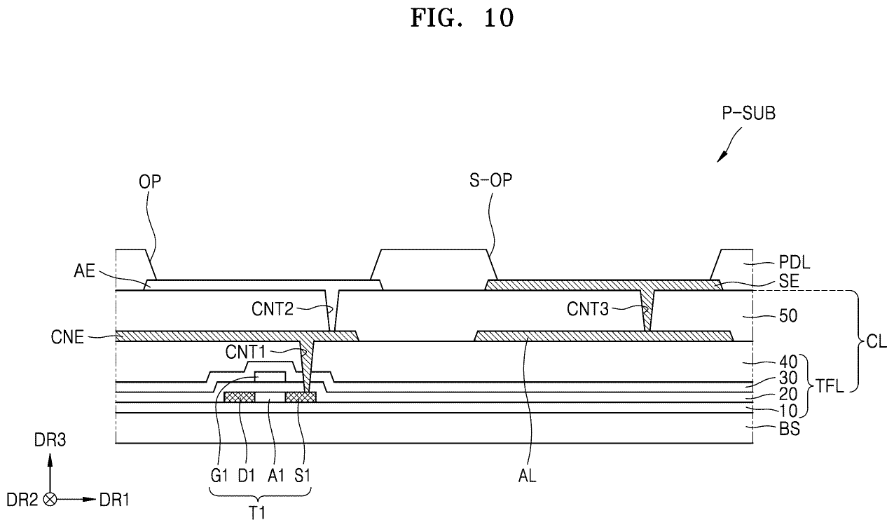

FIGS. 10 to 13 are cross-sectional views corresponding to a step of a method of manufacturing a display device according to an embodiment.

FIGS. 10 to 13 each correspond to the cross-sectional view illustrated in FIG. 7, and illustrate an example of a step of manufacturing the display panel DP including the embodiment in which the intermediate portion OL3 is arranged in FIG. 9.

A method of manufacturing a display panel according to an embodiment may include a substrate preparing step, a circuit layer forming step, a first electrode (pixel electrode) and auxiliary electrode forming step, an organic layer forming step, a hole area forming step, and a counter electrode forming step.

Here, the circuit layer forming step and the pixel electrode and auxiliary electrode forming step may be referred to as a target substrate preparing step.

For example, the target substrate preparing step may include preparing a target substrate on which a pixel electrode and an auxiliary electrode are formed. The organic layer forming step may include depositing a light-emitting stack including a plurality of organic layers and a charge generation layer on the pixel electrode and the auxiliary electrode.

In the hole area forming step, an opening OL-OP may be formed, in a laser drilling manner, through the components of an organic layer OL which is arranged to overlap the auxiliary electrode, and an area where the opening OL-OP is formed may be defined as an opening area. In the hole area forming step, an area by which the laser is irradiated may be designed to be at least a certain width to secure a sufficient contact area between a second electrode CE and the auxiliary electrode SE in a subsequent step. A portion of the organic layer of the light-emitting stack, exposed to the laser, may be pushed outward from the opening area to protrude upward, resulting in forming a protrusion.

In the hole area forming step, the auxiliary electrode SE may form a first area with a constant thickness and a second area with a variable thickness by a laser beam. For example, the hole area forming step may include an overprocessing step of forming the auxiliary electrode having the variable thickness. This will be described in detail later.

The counter electrode forming step may include depositing a counter electrode on the light-emitting stack and a through hole which overlap the pixel electrode. Accordingly, the counter electrode may be formed to oppose the pixel electrode and be electrically connected to the auxiliary electrode through the through hole.

FIG. 10 illustrates an example of a cross-section of a target substrate P-SUB prepared in the target substrate preparing step. Referring to FIG. 10, the target substrate P-SUB prepared in the target substrate preparing step may include a pixel electrode AE and an auxiliary electrode SE spaced apart from the pixel electrode AE. The target substrate P-SUB may correspond to a substrate prior to forming an organic layer OL on the pixel electrode AE and the auxiliary electrode SE.

The auxiliary electrode SE may be arranged at the same layer as the pixel electrode AE and may be formed by the same process as the pixel electrode AE. A fourth insulating layer 50 may be formed by a depositing method, such as spin coating or chemical vapor deposition, and thereafter contact holes CNT2 and CNT3 may be defined through the fourth insulating layer 50. The pixel electrode AE and the auxiliary electrode SE may be formed by depositing and patterning a metal layer on the fourth insulating layer 50. The pixel electrode AE and the auxiliary electrode SE may include the same material. Therefore, the number of overall processes to form the auxiliary electrode SE may not increase.

A pixel defining layer PDL may be formed between the pixel electrode AE and the auxiliary electrode SE. The pixel defining layer PDL may be formed on the pixel electrode AE and the auxiliary electrode SE in a coating or deposition manner, and thereafter, an emission opening OP which exposes a portion of the pixel electrode AE and an opening S-OP which exposes a portion of the auxiliary electrode SE may be formed through a mask process. The pixel defining layer PDL may have a certain thickness to secure a certain distance between an edge of the pixel electrode AE and the counter electrode CE. This may suppress concentration of an electric field at the edge of the pixel electrode AE, thereby suppressing a short circuit between the pixel electrode AE and the counter electrode CE.

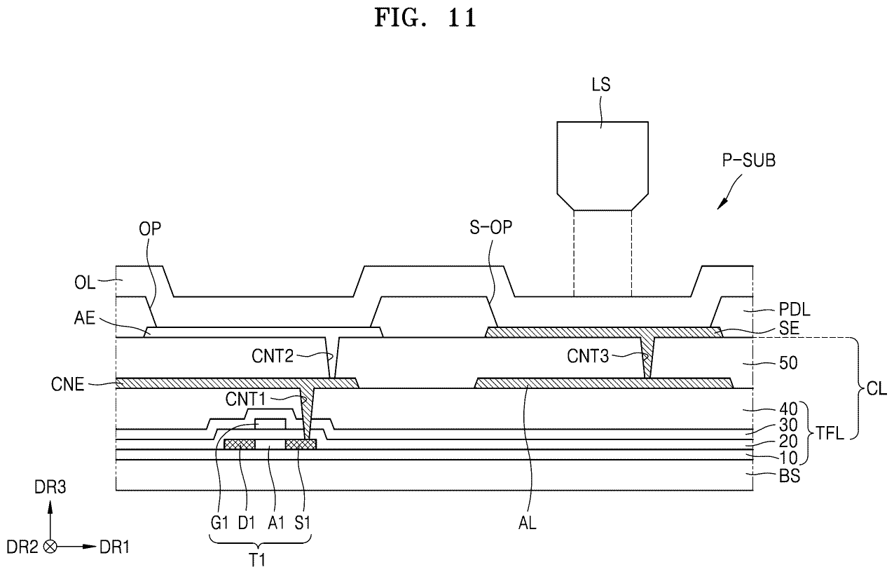

FIG. 11 corresponds to a cross-section of the target substrate P-SUB after the light-emitting stack forming step, and may correspond to the opening area and protrusion forming step. Referring to FIG. 11, the organic layer OL may be formed on the target substrate P-SUB of FIG. 10. The previous description of the organic layer OL may be applied in the same way, and a following description will focus on the process of forming the organic layer OL.

An emission layer and a functional layer included in the organic layer OL may be commonly formed in the emission area EA and the non-emission area NEA. The emission layer and the functional layer included in the organic layer OL may be formed as a common layer using an open mask. However, without being limited thereto, the emission layer among the layers included in the organic layer OL may be formed as a light-emitting pattern to be arranged corresponding to the pixel electrode AE.

A portion of the organic layer OL which is commonly formed in the emission area EA and the non-emission area NEA may be formed on the auxiliary electrode SE. A preliminary hole area where an opening penetrating the organic layer OL is to be formed may be defined in the organic layer OL overlapping the auxiliary electrode SE.

The laser may be provided as a Gaussian beam. For example, the laser may have a circular phase in a plan view. The phase of the laser may include a central area and an edge area surrounding the central area. Intensity of the laser corresponding to the central area may be stronger than intensity of the laser corresponding to the edge area.

The intensity of the laser corresponding to the central area may be sufficient to remove the organic layer OL. However, in case that the intensity of the laser corresponding to the central area increases, the auxiliary electrode below the organic layer may be deformed.

A wavelength of the laser may be in an ultraviolet wavelength range. For example, the wavelength of the laser may be in the range of 300 nm to 400 nm. However, the wavelength of the laser is not limited to the above numerical examples.

An output of the laser per unit area may be less than 200 millijoules per square centimeter (mJ/cm²). For example, the output of the laser per unit area may be in the range of 50 mJ/cm² to 200 mJ/cm². In case that the output of the laser per unit area is smaller than 50 mJ/cm², the components of the organic layer OL corresponding to the preliminary hole area may be insufficiently removed. In case that the output of the laser per unit area is at least 200 mJ/cm², the organic layer OL may be removed and the auxiliary electrode SE formed below the organic layer OL may also be damaged. However, this is an example, and the output of the laser per unit area may vary depending on conditions, such as the thickness and shape of the organic layer.

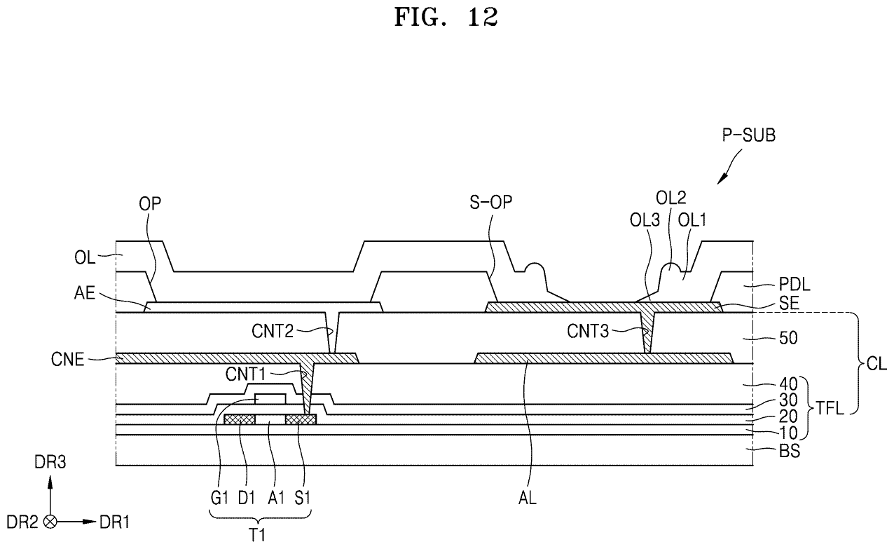

Referring to FIG. 12, corresponding to the central area of the laser, an opening area HA may be formed through the organic layer OL and may expose a portion of the auxiliary electrode SE. The opening area HA may correspond to an area of the auxiliary electrode SE which is exposed by an opening OL2 (see FIG. 9) of the organic layer OL formed to overlap the auxiliary electrode SE. The opening area HA may have a circular shape in a plan view, like the phase of the laser. A diameter of the opening area HA may be substantially equal to or smaller than the size of the laser. Therefore, the size of the opening area HA may be variously adjusted by adjusting the size of the laser.

An intermediate portion OL3 may be formed in the organic layer OL to correspond to the edge area of the laser. The intermediate portion OL3 may be a portion which is formed in an intermediate area MA adjacent to the opening area HA, and in which the organic layer OL partially remains without being completely removed because laser intensity at the edge area is weaker than that at the central area. A thickness of the intermediate portion OL3 may be thinner than a thickness of another portion where the organic layer OL is arranged. A protrusion OL2 may be formed on a periphery of the intermediate portion OL3. The intermediate portion OL3 and the protrusion OL2 may have a ring shape surrounding the opening area HA in a plan view. The protrusion OL2 may be formed such that organic materials of the organic layer OL are pushed outward without being removed during a laser irradiation process. The protrusion OL2 may be a portion where the organic layer OL is thicker than other portions, and a slope of a portion where the protrusion OL2 is arranged may be greater than a slope of the intermediate portion OL3. An area from an edge of the intermediate portion OL3 to an edge of the protrusion OL2 may be referred to as a protrusion area.

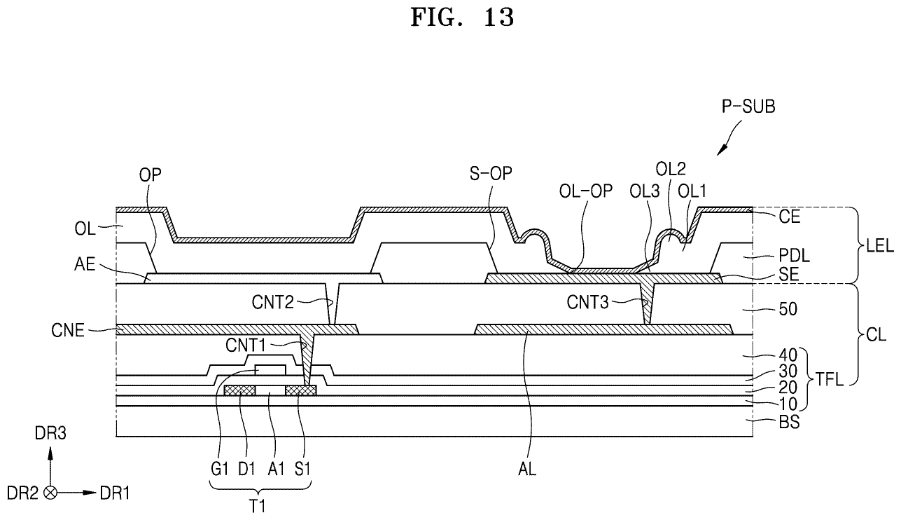

FIG. 13 illustrates a cross-section of a display panel DP on which a counter electrode CE has been formed through a counter electrode forming step. The counter electrode CE may be formed on the organic layer OL to oppose the pixel electrode AE, and may be formed through a deposition process on the opening area HA formed in the auxiliary electrode SE to be in contact with a portion of the auxiliary electrode SE.

In some embodiments, the method of manufacturing the display panel DP according to an embodiment may further include forming a capping layer CPL (see FIG. 9) and an encapsulation layer TFE (see FIG. 7) on the counter electrode CE after forming the counter electrode CE, depending on the configuration of the display panel DP. However, the idea of the disclosure is not limited to this.

A display panel DP according to an embodiment may suppress an IR drop phenomenon by bringing the second electrode CE into contact with the auxiliary electrode SE to which a second voltage is applied. Accordingly, the display panel DP may emit light with uniform brightness and suppress a phenomenon of emitting light more brightly in a partial area due to leakage current. In some embodiments, in a method of manufacturing a display panel DP according to an embodiment, in case of forming an opening OL-OP through which the second electrode CE and the auxiliary electrode SE are in contact with each other, the opening OL-OP may be formed in the organic layer by irradiating a laser beam. During the irradiation of the laser beam, a portion of the organic layer may be pushed outward such that a protrusion with an increased thickness is formed. In the display panel DP according to an embodiment, a width of the protrusion in one direction and the total number of openings OL-OP for contacting the second electrode CE and the auxiliary electrode SE may be set in a certain range, thereby suppressing the IR drop phenomenon and suppressing uneven brightness of pixels accordingly. Also, an aperture ratio of the display panel DP may be ensured to be at least a certain value, thereby suppressing a decrease in display efficiency of the display panel DP.

In some embodiments, the display panel DP according to an embodiment may form a plurality of hole areas, for example, the plurality of openings OL-OP, as described above. The hole forming step of the organic layer of the display panel DP may involve a process of forming the plurality of openings OL-OP, and a laser output may be inconstant for each opening OL-OP. For example, the output of the laser applied to each opening OL-OP may be slightly different.

Here, in case that the output of the laser exceeds an appropriate output, the organic layer may be removed and the auxiliary electrode SE below the organic layer may also be deformed.

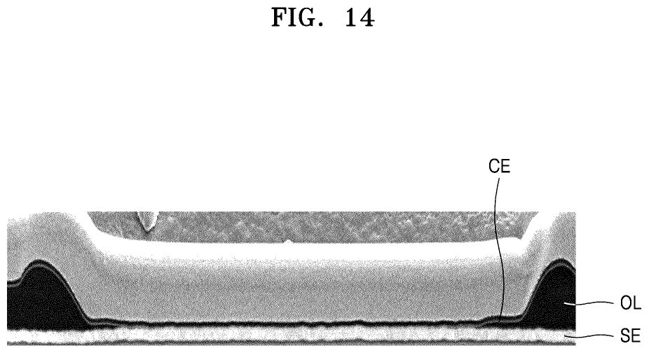

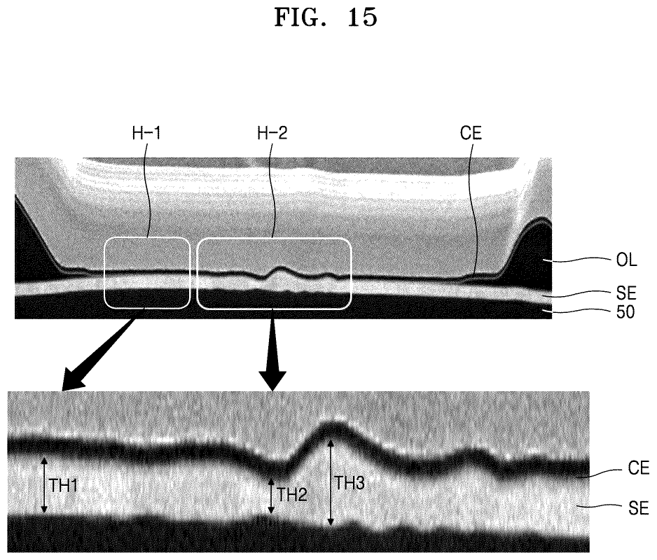

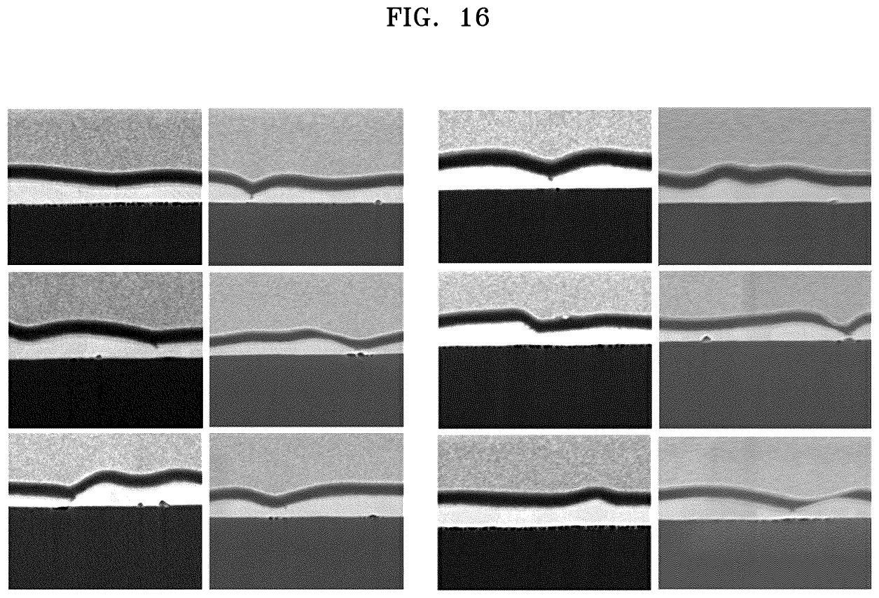

FIGS. 14 to 16 are photographs showing cross-sections of the organic layer and the auxiliary electrode SE in which the opening OL-OP is formed by laser irradiation, as in the display panel DP of FIG. 12. FIG. 14 shows a normally processed state of the auxiliary electrode SE, and FIG. 15 shows an overprocessed state in which a thickness change occurs in one area of the auxiliary electrode SE. FIG. 16 is a photograph showing various examples of the auxiliary electrode SE in the overprocessed state.

Referring to FIG. 14, in an embodiment, the auxiliary electrode SE which overlaps the opening OL-OP of the organic layer may have a constant thickness over an entire area. For example, the thickness of the auxiliary electrode SE in a contact portion with the second electrode CE may be the same as the thickness of the auxiliary electrode SE in an overlapped area with the organic layer OL.

Referring to FIG. 15, in an embodiment, the auxiliary electrode SE may have a thickness deviation. For example, the thickness of the auxiliary electrode SE may vary. Here, an area where the thickness of the auxiliary electrode SE is constant may be defined as a first area H-1, and an area where the thickness of the auxiliary electrode SE is variable may be defined as a second area H-2.

In some embodiments, the first area H-1 may have a constant thickness, and the thickness of the first area H-1 may be defined as a first thickness TH1. In the second area H-2, a thickness at a point with the minimum thickness may be defined as a second thickness TH2, and a thickness at a point with the maximum thickness may be defined as a third thickness TH3. Here, the second area H-2 may be connected to the first area H-1 and the thickness of the second area H-2 may vary between the third thickness TH3 as the maximum thickness and the second thickness TH2 as the minimum thickness. The thickness of the first area H-1 may be the same as a thickness of a portion of the auxiliary electrode SE overlapping the organic layer OL.

The first area H-1 and the second area H-2 of the auxiliary electrode SE may be formed in an area of the auxiliary electrode SE which overlaps the opening OL-OP. In some embodiments, in a plan view, the first area H-1 may be adjacent to an edge of the opening OL-OP, and the second area H-2 may overlap a center of the opening OL-OP in the plan view.

The thickness of the second area H-2 may be 5% to 300% of the first thickness TH1. For example, based on a thickness (i.e., the first thickness TH1) of the auxiliary electrode SE which is not damaged by virtue of an appropriate output, a damaged portion of the auxiliary electrode SE may have a thickness ranging from 5% to 300% of a normal thickness. For example, the second thickness TH2 may be 5% of the first thickness TH1, and the third thickness TH3 may be 300% of the first thickness TH1.

In this way, a thickness deviation may occur in the auxiliary electrode SE in case that a laser beam with an output greater than the appropriate output is irradiated to the auxiliary electrode SE. However, even in this case, the display panel may be driven without a fault in case that the auxiliary electrode SE is deformed to a thickness in a certain range.

The display panel DP according to an embodiment may have an overprocessed opening OL-OP and a normally processed opening OL-OP depending on the distribution of the laser output. For example, the display panel DP may include the auxiliary electrode SE with a thickness variation as well as the auxiliary electrode SE with a constant thickness.

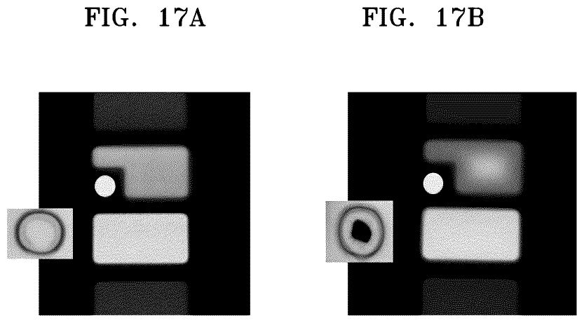

FIGS. 17A and 17B are photographs showing a phenomenon of pixel brightness unevenness that occurs in case that the thickness of the auxiliary electrode SE of the display panel DP is out of a certain range. FIG. 17A shows a pixel in a state where the opening OL-OP is normally processed, and FIG. 17B shows a pixel in a state where the opening OL-OP is overprocessed.

In case of forming the opening OL-OP of the organic layer OL by irradiating a laser beam, the auxiliary electrode SE may be damaged due to an excessive output of the laser. In case that the auxiliary electrode SE is deformed such that the thickness is 5% or less of the first thickness TH1, which is the normal thickness, an insulating layer arranged below the auxiliary electrode SE may be processed, which may increase out-gassing. This may cause a problem with uneven pixel brightness. Referring to FIG. 17B, it may be confirmed that discoloration has occurred in a red pixel.

TABLE 1

| | | |
|---|---|---|
| 90.00% | 91.80% | 90.30% |
| 97.10% | 93.80% | 96.10% |
| 95.30% | 100.00% | 95.00% |

Table 1 shows the results of evaluating the reliability characteristics of the display panel DP in case that the thickness deviation of at least 5% of the normal thickness occurs due to the deformation of the auxiliary electrode SE. In some embodiments, reliability was tested after 1000 hours of storage under a constant temperature of 85° C. and a constant humidity of 85%, and a brightness deviation was measured at nine points on the display panel DP. In case that about 80% of brightness with respect to a maximum 100% of brightness is a criterion of a brightness defect, referring to Table 1, it has been confirmed that there is no problem with suppressing an occurrence of an IR drop because all nine points exhibit at least 90% of brightness without a great brightness deviation.

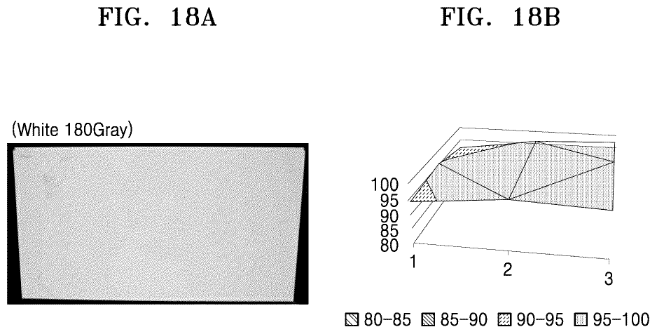

FIG. 18A is a photograph showing brightness and brightness contour map of a display device according to an embodiment.

FIG. 18A shows the brightness of the display panel DP according to the reliability test described in Table 1, and FIG. 18B shows the brightness contour map of the display panel DP according to the reliability test described in Table 1.

It may be confirmed that the display device DD according to an embodiment entirely exhibits uniform and high brightness upon displaying white.

Referring to an image and a graph showing the brightness of light with contour lines in case of displaying white equally on the display device DD, the display device DD according to an embodiment may entirely exhibit high brightness.

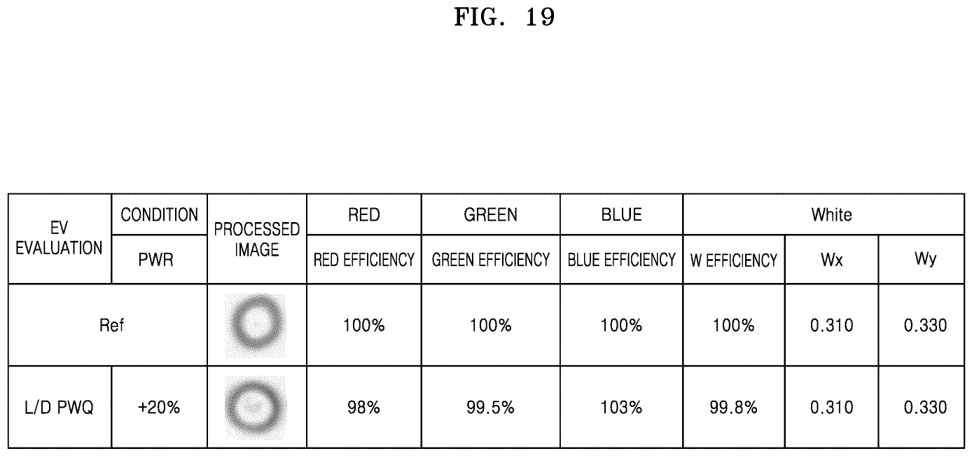

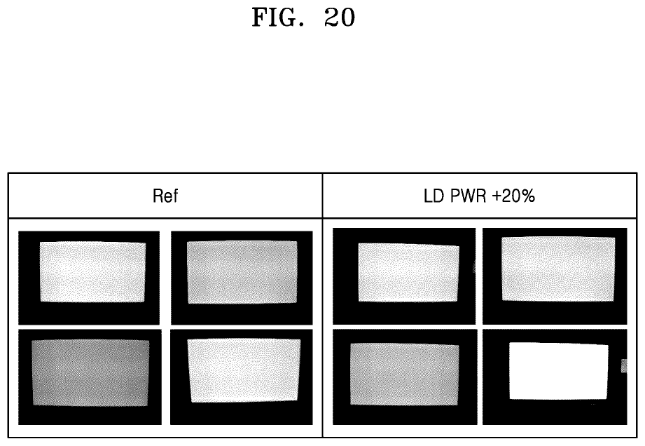

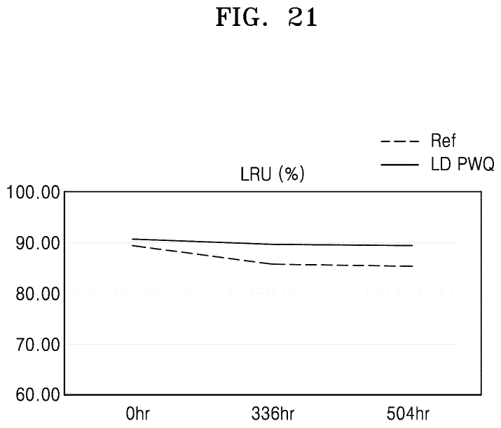

FIGS. 19 to 21 are tables showing the characteristic evaluation results of a display panel DP according to normal processing and overprocessing upon processing an organic layer hole of the display panel DP according to an embodiment. FIG. 19 is a table comparing properties, such as color coordinates and light efficiency, of display panels DP according to a comparative example and an embodiment, FIG. 20 is a photograph for checking brightness and staining of the display panels DP according to the comparative example and the embodiment, and FIG. 21 is a graph showing long range uniformity (LRU) of the display panels DP according to the comparative example and the embodiment.

A comparative example Ref indicates a normally processed display panel DP, and L/D PWQ indicates a display panel DP that has been overprocessed under the condition that a laser output is increased by 20%.

Referring to FIG. 19, in case of comparing the display panel DP according to the embodiment with the display panel DP according to the comparative example, it may be confirmed that there is no fault in red light efficiency, green light efficiency, blue light efficiency, white light efficiency, and color coordinate values.

Referring to FIG. 20, in case of comparing the display panel DP according to the embodiment with the display panel DP according to the comparative example, it may be confirmed that there is no problem with visibility because a brightness difference or staining does not occur.

Referring to FIG. 21, in case of comparing the display panel DP according to the embodiment with the display panel DP according to the comparative example, it may be confirmed that there is no fault as the LRU of approximately 90% is exhibited.

As confirmed above, the display panel in which the auxiliary electrode SE has the thickness deviation in the aforementioned numerical range by the overprocessing of the opening OL-OP may have the effect of suppressing the IR drop, similar to the display panel including the normally processed opening OL-OP.

In some embodiments, as described above, the display devices according to the disclosure may be applied to various fields, and this will be described in detail.

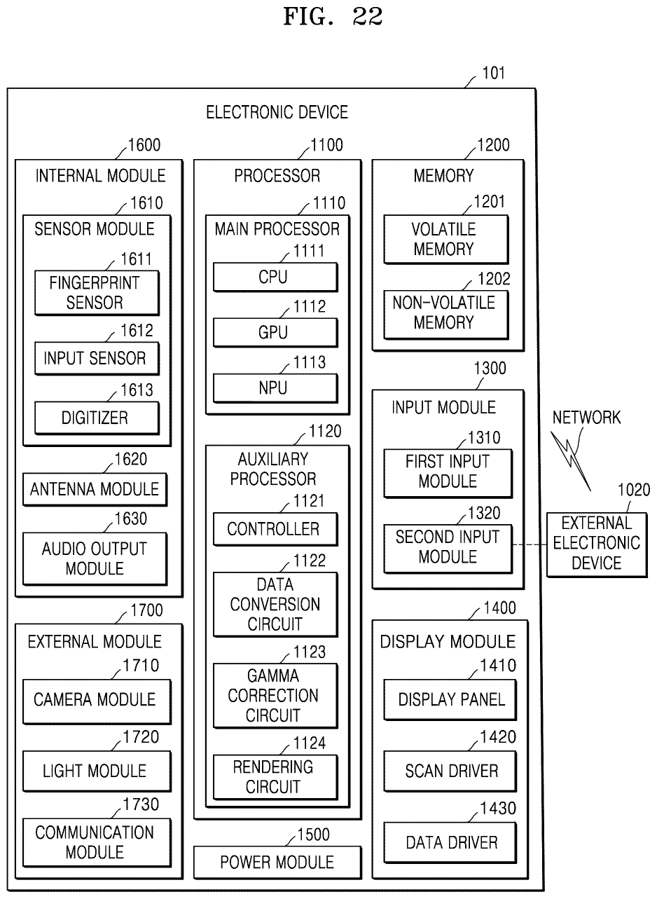

FIG. 22 is a block diagram of an electronic device according to embodiments. FIG. 22 is an example, in which an electronic device 101 may selectively include at least one or a plurality of components illustrated in FIG. 22 depending on the purpose and design condition of the electronic device 101.

The electronic device 101 may output various types of information through a display module 1400 in an operating system. The display module 1400 may correspond to the display device DD or the display module DM according to the aforementioned embodiment or at least a partial area of the display device DD or display module DM.

In case that a processor 1100 executes an application stored in a memory 1200, the display module 1400 may provide application information to a user through a display panel 1410.

The processor 1100 may obtain external input through an input module 1300 or a sensor module 1610 and execute an application corresponding to the external input. For example, when the user selects a camera icon displayed on the display panel 1410, the processor 1100 may obtain user input through an input sensor 1612 and activate a camera module 1710. The processor 1100 may transmit image data, which corresponds to a photographed image acquired through the camera module 1710, to the display module 1400. The display module 1400 may display an image corresponding to the photographed image through the display panel 1410.

As another example, in case that personal information authentication is performed on the display module 1400, a fingerprint sensor 1611 may acquire input fingerprint information as input data. The processor 1100 may compare the input data acquired through the fingerprint sensor 1611 with authentication data stored in the memory 1200, and execute an application based on a result of the comparison. The display module 1400 may display information executed according to a logic of the application through the display panel 1410.

As another example, in case that a music streaming icon displayed on the display module 1400 is selected, the processor 1100 may obtain user input through the input sensor 1612 and activate a music streaming application stored in the memory 1200. In case that a music execution command is input in the music streaming application, the processor 1100 may activate an audio output module 1630 to provide the user with audio information corresponding to the music execution command.

So far, the operation of the electronic device 101 has been briefly described. Hereinafter, the configuration of the electronic device 101 will be described in detail. Some of respective components of the electronic device 101 to be described below may be provided as one integrated component, and a single component may be separated and provided as two or more components.

Referring to FIG. 22, the electronic device 101 may communicate with an external electronic device 1020 via a network (e.g., a short-range wireless communication network or a long-range wireless communication network). According to an embodiment, the electronic device 101 may include a processor 1100, a memory 1200, an input module 1300, a display module 1400, a power module 1500, an internal module 1600, or an external module 1700. According to an embodiment, the electronic device 101 may exclude at least one of the components, or may additionally include at least one component. In an embodiment, some of the components described above (e.g., the sensor module 1610, the antenna module 1620, or the audio output module 1630) may be integrated into another component (e.g., the display module 1400).

The processor 1100 may execute software to control at least one other component (e.g., a hardware or software component) of the electronic device 101 connected to the processor 1100, and perform various data processing or operations. According to an embodiment, as at least some of the data processing or operations, the processor 1100 may store commands or data received from another component (e.g., the input module 1300, the sensor module 1610, or a communication module 1730) in a volatile memory 1201, process the commands or data stored in the volatile memory 1201, and store resultant data in a non-volatile memory 1202.

The processor 1100 may include a main processor 1110 and an auxiliary processor 1120. The main processor 1110 may include at least one of a central processing unit (CPU) 1111 or an application processor (AP). The main processor 1110 may further include at least one of a graphics processing unit (GPU) 1112, a communication processor (CP), or an image signal processor (ISP). The main processor 1110 may further include a neural processing unit (NPU) 1113. The NPU may be a processor specialized in processing an artificial intelligence model, and the artificial intelligence model may be created through machine learning. The artificial intelligence model may include a plurality of artificial neural network layers. An artificial neural network may be one of a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-network, or a combination of two or more of the networks, but is not limited to the examples described above. The artificial intelligence model may additionally or alternatively include a software structure in addition to a hardware structure. At least two of the processing units and processors described above may be implemented as a single integrated configuration (e.g., a single chip) or the respective processing units and processors may be implemented as independent configurations (e.g., a plurality of chips).

The auxiliary processor 1120 may include a controller 1121. The controller 1121 may include an interface conversion circuit and a timing control circuit. The controller 1121 may receive an image signal from the main processor 1110, and output image data by converting a data format of the image signal to comply with an interface specification with the display module 1400. The controller 1121 may output various control signals, which are required for operation of the display module 1400.

The auxiliary processor 1120 may further include a controller 1121, a data conversion circuit 1122, a gamma correction circuit 1123, a rendering circuit 1124, and the like. The data conversion circuit 1122 may receive image data from the controller 1121, and compensate for the image data so that the image is displayed at a desired brightness according to the characteristics of the electronic device 101 or user settings, or may convert the image data to reduce power consumption or compensate for afterimages. The gamma correction circuit 1123 may convert image data or a gamma reference voltage, so that an image displayed on the electronic device 101 has desired gamma characteristics. The rendering circuit 1124 may receive image data from the controller 1121 and render the image data by taking into consideration a pixel arrangement of the display panel 1410 applied to the electronic device 101. At least one of the data conversion circuit 1122, the gamma correction circuit 1123, or the rendering circuit 1124 may be integrated into another component (e.g., the main processor 1110 or the controller 1121). At least one of the data conversion circuit 1122, the gamma correction circuit 1123, or the rendering circuit 1124 may be integrated into a data driver 1430 to be described later.

The memory 1200 may store various kinds of data used by at least one component of the electronic device 101 (e.g., the processor 1100 or the sensor module 1610) and input data or output data for commands related to the various kinds of data. The memory 1200 may include at least one of a volatile memory 1201 or a non-volatile memory 1202.

The input module 1300 may receive commands or data to be used in a component of the electronic device 101 (e.g., the processor 1100, the sensor module 1610, or the audio output module 1630) from the exterior of the electronic device 101 (e.g., the user or the external electronic device 1020).

The input module 1300 may include a first input module 1310 into which a command or data is input from the user, and a second input module 1320 into which a command or data is input from the external electronic device 1020. The first input module 1310 may include a microphone, a mouse, a keyboard, keys (e.g., buttons), or a pen (e.g., a passive pen or an active pen). The second input module 1320 may support a designated protocol that may be connected wiredly or wirelessly with the external electronic device 1020. According to an embodiment, the second input module 1320 may include a high definition multimedia interface (HDMI), a universal serial bus (USB) interface, an SD card interface, or an audio interface. The second input module 1320 may include a connector that may be physically connected to the external electronic device 1020, for example, an HDMI connector, a USB connector, an SD card connector, or an audio connector (e.g., a headphone connector).

The display module 1400 may provide information visually to the user. The display module 1400 may include a display panel 1410, a scan driver 1420, and a data driver 1430.

The display module 1400 and the display panel 1410 described with reference to FIG. 22 may correspond to the display module DM or display panel DP of the above-described embodiment.

The display panel 1410 may further include an emission driver. The emission driver may output an emission control signal to the display panel 1410, in response to a control signal received from the controller 1121. The emission driver may be formed separately from the scan driver 1420 or may be integrated into the scan driver 1420.

The scan driver 1420 may receive a control signal from the controller 1121, and output scan signals to the display panel 1410, in response to the control signal.

The data driver 1430 may receive a control signal from the controller 1121, convert image data into analog voltages (e.g., data voltages), in response to the control signal, and output the data voltages to the display panel 1410.

The data driver 1430 may be integrated into another component (e.g., the controller 1121). The functions of the interface conversion circuit and the timing control circuit of the controller 1121 may also be integrated into the data driver 1430.

The display module 1400 may further include an emission driver, a voltage generation circuit, and the like. The voltage generation circuit may output various voltages required for driving the display panel 1410.

The power module 1500 may supply power to respective components of the electronic device 101. For example, the power module 1500 may generate a first voltage ELVDD and a second voltage ELVSS. The power module 1500 may generate a gate driving voltage (e.g., a gate high voltage or a gate low voltage) required to drive the scan driver 1420.

For example, the power module 1500 may refer to a power generation unit, a power supply, or the like. As an example, the power module 1500 may include a battery that charges a power voltage. The battery may include a non-rechargeable primary battery, a rechargeable secondary battery, or a fuel cell.

For example, the power module 1500 may include a power management integrated circuit (PMIC). The PMIC may supply power optimized for each of the modules described above and modules to be described later.

For example, the power module 1500 may include a wireless power transmission and reception member electrically connected to the battery. The wireless power transmission and reception member may include a plurality of coil-shaped antenna radiators.

The electronic device 101 may further include an internal module 1600 and an external module 1700. The internal module 1600 may include a sensor module 1610, an antenna module 1620, and an audio output module 1630. The external module 1700 may include a camera module 1710, a light module 1720, and a communication module 1730.

The sensor module 1610 may detect input by the user's body or input by a pen of the first input module 1310, and generate an electric signal or data value in response to the input. The sensor module 1610 may include at least one of a fingerprint sensor 1611, an input sensor 1612, or a digitizer 1613.

The fingerprint sensor 1611 may generate a data value corresponding to the user's fingerprint. The fingerprint sensor 1611 may include any one of an optical fingerprint sensor or a capacitive fingerprint sensor.

The input sensor 1612 may generate a data value corresponding to coordinate information about input by the user's body or input by the pen. The input sensor 1612 may generate a data value based on the change in capacitance due to input. The input sensor 1612 may detect input by a passive pen or transmit and receive data to and from an active pen.

The input sensor 1612 may also measure a bio-signal, such as blood pressure, moisture, or body fat. For example, when the user does not move for a certain period of time while touching a portion of his or her body to a sensor layer or sensing panel, the input sensor 1612 may detect a bio-signal based on a change in electric field caused by the portion of his or her body, and output information desired by the user to the display module 1400.

The digitizer 1613 may generate a data value corresponding to coordinate information input by the pen. The digitizer 1613 may generate a data value based on an electromagnetic change by input. The digitizer 1613 may detect input by the passive pen or transmit and receive data to and from the active pen.

At least one of the fingerprint sensor 1611, the input sensor 1612, or the digitizer 1613 may be implemented as a sensor layer formed on the display panel 1410 through a continuous process. The fingerprint sensor 1611, the input sensor 1612, and the digitizer 1613 may be arranged on the display panel 1410, and any one of the fingerprint sensor 1611, the input sensor 1612, or the digitizer 1613, for example, the digitizer 1613, may be arranged below the display panel 1410.

At least two of the fingerprint sensor 1611, the input sensor 1612, or the digitizer 1613 may be formed to be integrated into a single sensing panel through the same process. In case of being integrated into a single sensing panel, the sensing panel may be arranged on the display panel 1410, or as another example, may be arranged on a window member arranged on the display panel 1410. The position of the sensing panel may be variously determined by controlling conditions of other manufacturing processes.

As an optional embodiment, at least one of the fingerprint sensor 1611, the input sensor 1612, or the digitizer 1613 may be embedded in the display panel 1410. For example, at least one of the fingerprint sensor 1611, the input sensor 1612, or the digitizer 1613 may be formed simultaneously through a process of forming elements (e.g., light-emitting elements, transistors, or the like) included in the display panel 1410.

In some embodiments, the sensor module 1610 may generate an electrical signal or data value corresponding to an internal or external state of the electronic device 101. The sensor module 1610 may further include, for example, a gesture sensor, a gyro sensor, an air pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 1620 may include at least one antenna for transmitting signals or power to or receiving signals or power from the exterior. According to an embodiment, the communication module 1730 may transmit a signal to an external electronic device or receive a signal from the external electronic device through an antenna suitable for a communication method. An antenna pattern of the antenna module 1620 may be integrated into one component of the display module 1400 (e.g., the display panel 1410) or the input sensor 1612.

The audio output module 1630 may be a device for outputting audio signals to the outside of the electronic device 101, and may include, for example, a speaker used for general purposes, such as playing multimedia or playing record, and a receiver used exclusively for incoming calls. According to an embodiment, the receiver may be formed integrally with or separately from the speaker. An audio output pattern of the audio output module 1630 may also be integrated into the display module 1400.

The camera module 1710 may capture still images and moving images (videos). According to an embodiment, the camera module 1710 may include at least one of a lens, an image sensor, or an image signal processor. The camera module 1710 may further include an infrared camera which may measure presence or absence of a user, the user's location, the user's gaze, and the like.

The light module 1720 may provide light. The light module 1720 may include a light-emitting diode or a xenon lamp. The light module 1720 may operate in conjunction with the camera module 1710 or independently.

The communication module 1730 may support establishment of a wired or wireless communication channel between the electronic device 101 and the external electronic device 1020, and performance of communication through the established communication channel. The communication module 1730 may include one or all of a wireless communication module, such as a cellular communication module, a short-range wireless communication module, or a global navigation satellite system (GNSS) communication module, and a wired communication module, such as a local area network (LAN) communication module, or a power line communication module. The communication module 1730 may communicate with the external electronic device 1020 via a short-range communication network, such as Bluetooth, WiFi direct, or infrared data association (IrDA), or a long-range communication network, such as a cellular network, the Internet, or a computer network (e.g., a LAN or WAN). The various types of communication modules 1730 described above may be implemented as one chip or as separate chips.

The input module 1300, the sensor module 1610, the camera module 1710, and the like may be used to control the operation of the display module 1400 in conjunction with the processor 1100.

The processor 1100 may output a command or data to the display module 1400, the audio output module 1630, the camera module 1710, or the light module 1720 based on input data received from the input module 1300. For example, the processor 1100 may generate image data in response to input data received through a mouse, an active pen, or the like, and output the generated image data to the display module 1400, or may generate command data in response to the input data and output the generated command data to the camera module 1710 or the light module 1720. In case that no input data is received from the input module 1300 for a certain period of time, the processor 1100 may switch an operation mode of the electronic device 101 to a low-power mode or sleep mode to reduce power consumption of the electronic device 101.

The processor 1100 may output a command or data to the display module 1400, the audio output module 1630, the camera module 1710, or the light module 1720 based on sensing data received from the sensor module 1610. For example, the processor 1100 may compare authentication data applied by the fingerprint sensor 1611 with authentication data stored in the memory 1200, and execute an application based on a result of the comparison. The processor 1100 may execute a command or output corresponding image data to the display module 1400 based on sensing data detected by the input sensor 1612 or the digitizer 1613. In case that a temperature sensor is included in the sensor module 1610, the processor 1100 may receive temperature data on a measured temperature from the sensor module 1610, and further perform brightness correction or the like on image data based on the temperature data.

The processor 1100 may receive measurement data on the presence or absence of a user, the user's location, the user's gaze, and the like from the camera module 1710. The processor 1100 may further perform brightness correction and the like on image data based on the measurement data. For example, the processor 1100 which has determined the presence or absence of the user through input from the camera module 1710 may output image data, which has brightness corrected through the data conversion circuit 1122 or the gamma correction circuit 1123, to the display module 1400.

Some of the components may be connected to each other through a communication method between peripheral devices, for example, a bus, general purpose input/output (GPIO), serial peripheral interface (SPI), mobile industry processor interface (MIPI), or ultra path interconnect (UPI) link, to exchange signals (e.g., commands or data) with each other. The processor 1100 may communicate with the display module 1400 through a mutually agreed interface, and for example, may use any one of the aforementioned communication methods, and the communication method is not limited to the aforementioned communication methods.

The electronic device 101 according to various embodiments disclosed herein may be various type of devices. The electronic device 101 may include, for example, at least one of a portable communication device (e.g., a smartphone), a computer device, a portable multimedia device, a portable medical device, a camera, a wearable device, or a home appliance device. The electronic device 101 according to an embodiment is not limited to the devices described above.

Hereinafter, an implementation of the electronic device 101 will be described in detail.

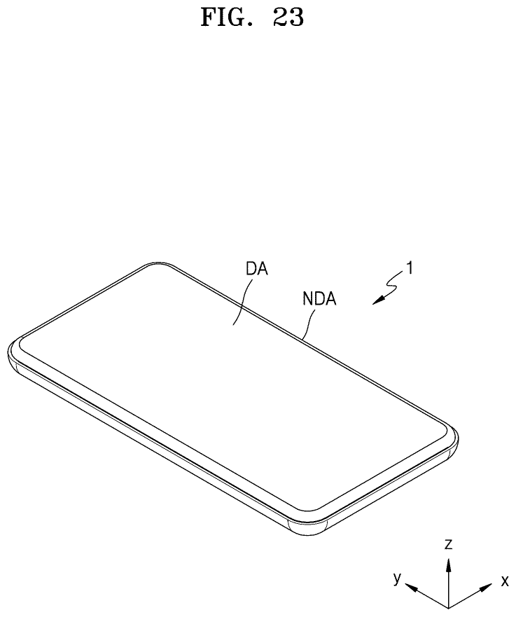

FIG. 23 is a view for explaining another electronic device to which a display device according to an embodiment is applied.

The above-described display device, for example, the display device DD, may be easily applied to various electronic devices.

For example, the display device DD according to the above-described embodiments may be various products or parts thereof, such as a television, a laptop computer, a monitor, a billboard, the Internet of Things, as well as portable electronic devices, such as a mobile phone, a smartphone, a tablet personal computer (PC), a mobile communication terminal, an electronic organizer, an electronic book, a portable multimedia player (PMP), a navigation, and an ultra-mobile PC (UMPC).

The display device DD according to the aforementioned embodiments may also be wearable devices or parts thereof, such as a smart watch, a watch phone, a glasses-type display, or a head mounted display (HMD).

Of course, the disclosure is not limited to this. For example, the display device DD according to the embodiments described above may be included in a dashboard of a vehicle, a center information display (CID) arranged on a center fascia or dashboard of a vehicle, a room mirror display replacing a side mirror of a vehicle, a display arranged on the rear side of a front seat to serve as an entertainment device for back seat passengers of a vehicle, a head-up display (HUD) installed on the front of a vehicle or projected on front window glass, and a computer-generated hologram augmented reality head-up display (CGH AR HUD).

For example, referring to FIG. 23, an example is illustrated in which an electronic device 2000 to which the display device DD according to the above-described embodiments is applied is a smart phone.

The electronic device 2000 may include a display area DA and a non-display area NDA outside the display area DA. The display area DA may overlap the display area DA of the display device DD described above, or as another example, may be partially obscured by the display area DA of the display device DD. The non-display area NDA of the electronic device 2000 may be an area where an image is not displayed, and may be an area that overlaps fully or partially the non-display area NDA of the display device DD. Drivers for applying electrical signals or power to display elements arranged in the display area DA may be arranged in the non-display area NDA of the electronic device 2000, and pads which are areas to which electronic elements or printed circuit boards may be electrically connected, may also be arranged in the non-display area NDA of the electronic device 2000. Although not illustrated, the electronic device 2000 that is the smart phone may be of a rigid type, or as another example, may include various types, such as a bending type in which one or opposite sides are bent, or a foldable type in which the device is folded more than once.

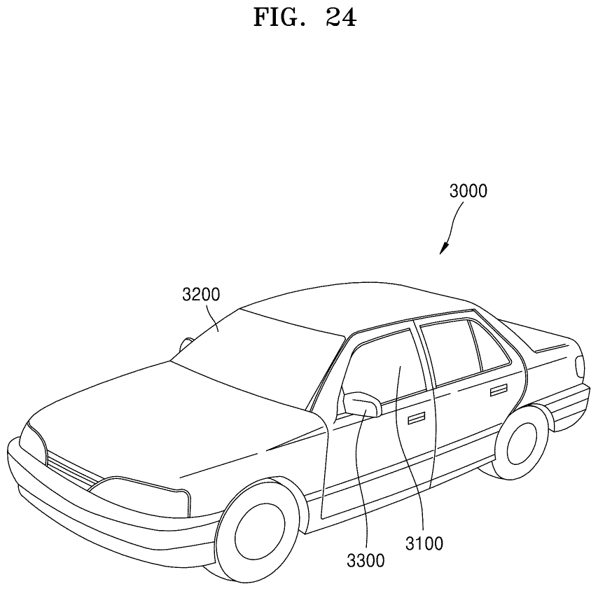

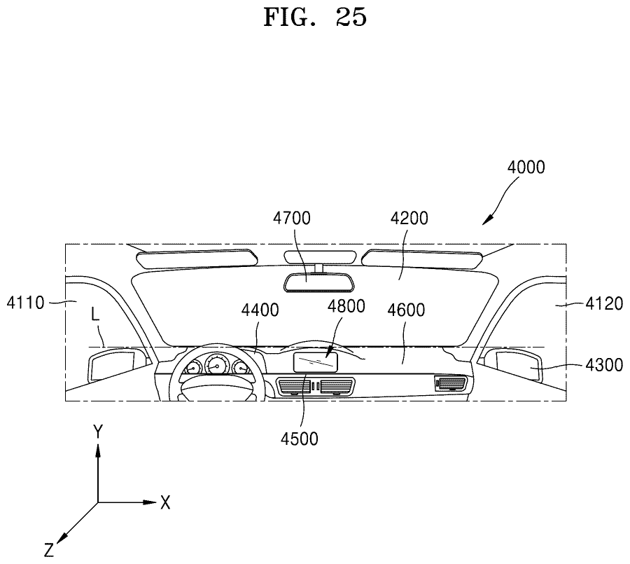

FIGS. 24 and 25 are views for explaining still another electronic device to which a display device according to an embodiment is applied.

FIG. 24 is a schematic diagram of the exterior of a transport device 3000 to which a display device is applied as a specific example.

The transport device 3000 may refer to various devices for moving a target to be transported, such as a human, an object, or an animal, and may include a vehicle traveling on a road or a track, a vessel moving over the sea or river, and an airplane flying in the sky using the action of air.

The transport device 3000 may also move in a certain direction according to rotation of at least one wheel. For example, the transport device 3000 may include a three-wheeled or four-wheeled vehicle, a construction machine, a two-wheeled vehicle, a motor device, a bicycle, and a train running on a rail.

The transport device 3000 may include a body having an interior and an exterior, and a remaining part except for the body, for example, a chassis in which mechanical devices necessary for traveling are installed. The exterior of the body may include a front panel, a bonnet, a roof panel, a rear panel, a trunk, and a filler arranged at a boundary between doors.

The chassis of the transport device 3000 may include a power generation device, a power transmission device, a traveling device, a steering device, a braking device, a suspension device, a transmission device, a fuel device, left and right wheels at the front and rear, and the like.

The transport device 3000 may include side window glass 3100, front window glass 3200, and a side mirror 3300.

The display device DD according to the above-described embodiments may be applied to one area of the transport device 3000, for example, one of the side window glass 3100, the front window glass 3200, and the side mirror 3300. A user, for example, a driver or passenger of the transport device 3000, may visually check information inside the transport device 3000 through one of the window glass 3100, the front window glass 3200, and the side mirror 3300. The user may also perform a touch operation to input desired information, and proceed touch sensing and information processing through a touch sensing unit. Alternatively, even outside the transport device, for example, a vehicle, the driver or passenger or persons outside the vehicle may view various information displayed on the transport device 3000.

FIG. 25 is a schematic view of the interior of a transport device 4000 to which the display device is applied, as a detailed example.

The interior of the transport device 4000 may include a cluster 4400, a center fascia 4500, and a passenger-seat dashboard 4600.

The transport device 4000 may also include side window glasses 4100, and the side window glasses 4100 may include first side window glass 4110 and second side window glass 4120.

At least one side mirror 4300 may be included in the transport device 4000. The cluster 4400 may be located in front of a steering wheel. The cluster 4400 may include a tachometer, speedometer, a coolant thermometer, a fuel gauge indicator light, a high beam indicator light, a warning light, a seat belt warning light, a trochometer, an odometer, an automatic shift selection lever indicator light, a door open warning light, an engine oil warning light, and/or a low fuel warning light.

The center fascia 4500 may include a control panel on which a plurality of buttons for controlling an audio device, an air conditioning device, and a seat heater are located. The center fascia 4500 may be arranged on one side of the cluster 4400.

The passenger-seat dashboard 4600 may be arranged on one side of the center fascia 4500.

The display device DD according to the above-described embodiments may be applied to one area of the transport device 4000, for example, at least one of the cluster 4400, the center fascia 4500, or the passenger-seat dashboard 4600, and, as another example, to a rear mirror portion 4700. Accordingly, the user, for example, the driver or passenger of the transport device 4000, may visually check information through at least one of the cluster 4400, the center fascia 4500, the passenger-seat dashboard 4600, or the rear mirror portion 4700 inside the transport device 4000, perform a touch operation for an input such as information checking, and perform touch sensing and information processing through the touch sensing unit.

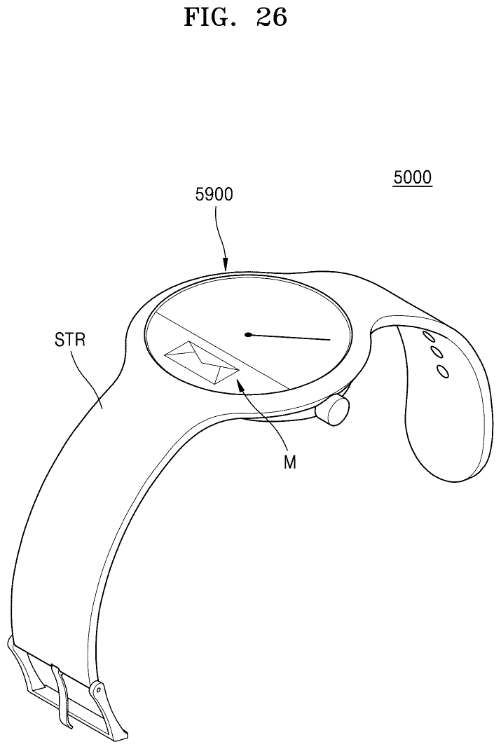

FIG. 26 is a view for explaining another electronic device to which a display device according to an embodiment is applied.

The above-described display device, for example, the display device DD, may be easily applied to various electronic devices, for example, an electronic device carried or worn by a user, as a detailed example, a wearable device.

Referring to FIG. 26, in one example, the electronic device may be a wearable electronic device 5000, and as a detailed example, may be a smart watch.

The wearable electronic device 5000 may include a main body 5900 and a stationary part STR. The main body 5900 may display an image IM having certain information.

The image IM may be implemented through the aforementioned display device DD, and, for example, may be implemented using light emitted from at least one emission area. An area where the image IM is displayed may include an area where a user's touch is sensed, for example, an area where a touch sensing unit having a touch electrode is arranged. Through this, the user may check the image IM on the main body 5900 while wearing or carrying the wearable electronic device 5000 or perform an input operation by applying a touch directly or using a touch pen. In some examples, the main body 5900 may include the aforementioned display device DD.

The image IM may be an icon or execution screen of an application executed by an application processor (not illustrated) as well as an image which realizes an existing analog clock, such as hands of a clock indicating a current time.

The main body 5900 may be detachably coupled to the stationary part STR. The user may wear the stationary part STR on his or her wrist to use the wearable electronic device 5000 on his or her wrist. The stationary part STR may have the shape of a strap, but is not limited to the purpose of being worn on the user's wrist. The stationary part STR may be of a type to be worn on the user's arm or neck, or may be replaced with a cradle for mounting the main body 5900 to another electronic device.

According to one or more embodiments, a display device with uniform brightness and improved reliability and a method of manufacturing the same may be provided.

However, the effect is exemplary and the effects of the disclosure are not limited thereto.

Each of the embodiments described above may be implemented independently, but of course, the structure of each embodiment may be applied in combination to other embodiments.

As such, the disclosure has been described with reference to the embodiments illustrated in the drawings, but is merely illustrative, and it will be understood by those skilled in the art that various modifications and variations of the embodiments may be made. Therefore, the true technical protection scope of the disclosure should be defined by the technical idea of the appended claims.

The specific executions described in the embodiments are merely illustrative, and do not limit the scope of the disclosure in any way. Furthermore, unless otherwise indicated obviously by terms, such as “essential,” “important,” and the like, a component may not be a necessary component for the application of the disclosure.

In the specification (particularly, in the claims) of the embodiment, the use of the term “the” and similar referential terms may refer to both the singular and the plural. Also, when a range is described in the embodiment, an invention to which individual values belonging to the range are applied is included (unless otherwise described contrarily), and each individual value constituting the range is described in the detailed description. Finally, the steps of the method according to the embodiment may be performed in any suitable order unless otherwise explicitly indicated herein or otherwise clearly contradicted by context. The embodiments are not necessarily limited by the order of steps described above. The use of any examples or illustrative terms in the embodiment is merely to describe the embodiment in detail, and unless limited by the claims, the scope of the embodiment is not limited by the examples or illustrative terms. Further, it will be understood by those skilled in the art that various modifications, combinations and changes may be made depending on design conditions and factors within the scope of the appended claims or their equivalents.

What is claimed is:

1. A display device comprising:
a substrate;
a circuit layer arranged on the substrate;
a first electrode arranged on the circuit layer;
at least one auxiliary electrode arranged on the circuit layer and electrically separated from the first electrode;
an organic layer arranged on the first electrode and the at least one auxiliary electrode, the organic layer defining an opening therein exposing a portion of the at least one auxiliary electrode; and
a second electrode arranged on the organic layer to overlap the first electrode and the at least one auxiliary electrode,
wherein the second electrode is electrically connected to the at least one auxiliary electrode through the opening of the organic layer, and
the at least one auxiliary electrode comprises a first auxiliary electrode having a variable thickness.

2. The display device of claim 1, wherein
the first auxiliary electrode comprises:
a first area having a constant first thickness; and
a second area connected to the first area and having a thickness which varies between a second thickness as a maximum thickness and a third thickness as a minimum thickness.

3. The display device of claim 2, wherein
the second area is formed in an area of the first auxiliary electrode, which overlaps the opening in a plan view.

4. The display device of claim 3, wherein
the first area is adjacent to an edge of the opening, and
the second area overlaps a center of the opening in the plan view.

5. The display device of claim 2, wherein
the thickness of the second area ranges from 5% to 300% of the constant first thickness.

6. The display device of claim 1, wherein
the at least one auxiliary electrode further comprises a second auxiliary electrode having a constant thickness.

7. The display device of claim 1, wherein
the circuit layer comprises a transistor layer and an insulating layer arranged on the transistor layer, and the first auxiliary electrode is arranged on the insulating layer.

8. The display device of claim 1, wherein
the organic layer comprises an emission layer, and the second electrode is directly connected to the at least one auxiliary electrode through the opening such that the emission layer is not disposed between the second electrode and the at least one auxiliary electrode.

9. The display device of claim 1, wherein
the first auxiliary electrode is arranged at a same layer as the first electrode.

10. A method of manufacturing a display device, the method comprising:
preparing a substrate;
forming a circuit layer on the substrate;
forming a first electrode and at least one auxiliary electrode electrically separated from the first electrode on the circuit layer;
forming an organic layer comprising an emission layer on the first electrode and the at least one auxiliary electrode;
forming an opening penetrating the organic layer and forming an auxiliary electrode of the at least one auxiliary electrode into a first auxiliary electrode having a variable thickness; and
forming a second electrode on the organic layer to overlap the first electrode and the at least one auxiliary electrode,
wherein the second electrode is electrically connected to the at least one auxiliary electrode through the opening of the organic layer.

11. The method of claim 10, wherein
the forming the opening and forming the auxiliary electrode into the first auxiliary electrode comprises a process of irradiating a laser beam onto the organic layer.

12. The method of claim 11, wherein
the first auxiliary electrode comprises:
a first area having a constant first thickness; and
a second area connected to the first area and having a thickness which varies between a second thickness as a maximum thickness and a third thickness as a minimum thickness.

13. The method of claim 12, wherein
the thickness of the second area ranges from 5% to 300% of the constant first thickness.

14. An electronic device comprising:
an input module, which receives a command or data to be used in the electronic device from outside;
a processor, which processes input data received from the input module and outputs image data or command data;
a memory, which stores input data or output data used by the processor; and
a display device, which implements at least one image by the processor,
wherein the display device comprises:
a first electrode arranged on a circuit layer;
at least one auxiliary electrode arranged on the circuit layer and electrically separated from the first electrode;
an organic layer arranged on the first electrode and the at least one auxiliary electrode, the organic layer defining an opening therein exposing a portion of the at least one auxiliary electrode; and
a second electrode arranged on the organic layer to overlap the first electrode and the at least one auxiliary electrode,
wherein the second electrode is electrically connected to the at least one auxiliary electrode through the opening of the organic layer, and
the at least one auxiliary electrode comprises a first auxiliary electrode having a variable thickness.

15. The electronic device of claim 14, wherein
the first auxiliary electrode comprises:
a first area having a constant first thickness; and
a second area connected to the first area and having a thickness which varies between a second thickness as a maximum thickness and a third thickness as a minimum thickness.

16. The electronic device of claim 15, wherein
the second area is formed in an area of the first auxiliary electrode which overlaps the opening in a plan view.

17. The electronic device of claim 16, wherein
the first area is adjacent to an edge of the opening, and
the second area overlaps a center of the opening in the plan view.

18. The electronic device of claim 15, wherein
the thickness of the second area ranges from 5% to 300% of the constant first thickness.

19. The electronic device of claim 14, wherein
the at least one auxiliary electrode further comprises a second auxiliary electrode having a constant thickness.

20. The electronic device of claim 14, wherein
the circuit layer comprises a transistor layer and an insulating layer arranged on the transistor layer, and the first auxiliary electrode is arranged on the insulating layer.
